(19) United States
(12) Patent Application Publication
(10) Pub. No.: US 2026/0114028 A1
(43) Pub. Date: Apr. 23, 2026

(54) NITRIDE SEMICONDUCTOR DEVICE AND METHOD FOR MANUFACTURING THE SAME

(71) Applicant: Nuvoton Technology Corporation Japan, Kyoto (JP)

(72) Inventor: Yusuke KANDA, Kyoto (JP)

(21) Appl. No.: 19/423,481

(22) Filed: Dec. 17, 2025

Related U.S. Application Data
(63) Continuation of application No. PCT/JP2024/023920, filed on Jul. 2, 2024.
(60) Provisional application No. 63/525,283, filed on Jul. 6, 2023.

(51) Int. Cl. H10D 84/80; H10D 1/00; H10D 1/47; H10D 1/68; H10D 30/01; H10D 30/47; H10D 62/60; H10D 62/824; H10D 84/01

(52) U.S. Cl. CPC H10D 84/813; H10D 1/021; H10D 1/041; H10D 1/474; H10D 1/694; H10D 30/015; H10D 30/475; H10D 62/60; H10D 62/824; H10D 84/01; H10D 84/817

(57) ABSTRACT

A nitride semiconductor device is a nitride semiconductor device including an active element and a passive element, and includes: a nitride semiconductor layer divided into an active region and an inactive region in a plan view; and a metal layer in contact with the nitride semiconductor layer in the inactive region. The active element is provided in the active region, and the passive element is provided in the inactive region. The metal layer includes a coherent state or a metamorphic state relative to the nitride semiconductor layer.

### CROSS REFERENCE TO RELATED APPLICATIONS

This is a continuation application of PCT International Patent Application No. PCT/JP2024/023920 filed on Jul. 2, 2024, designating the United States of America, which is based on and claims priority of U.S. Provisional Patent Application No. 63/525,283 filed on Jul. 6, 2023. The entire disclosures of the above-identified applications, including the specifications, drawings and claims are incorporated herein by reference in their entirety.

### FIELD

The present disclosure relates to nitride semiconductor devices and methods for manufacturing the same.

### BACKGROUND

Patent Literature (PTL) 1 discloses an electronic device that includes a GaN layer, an AlGaN layer provided on the GaN layer, a p-type GaN layer provided on the AlGaN layer, and an inductor including a metal layer provided on the p-type GaN layer.

### CITATION LIST

### Patent Literature

PTL 1: U.S. Pat. No. 11,038,048

### SUMMARY

### Technical Problem

When a semiconductor layer in contact with a metal layer includes carriers, a depletion layer extending from an interface with the metal layer is formed in the semiconductor layer. The formed depletion layer causes an increase in parasitic capacitance. The parasitic capacitance may cause wiring delays when the device is operated at a high frequency. In addition, the parasitic capacitance changes in magnitude as a carrier density varies due to the state of a voltage applied to the device. As a result, the high-frequency operation variation can occur. As stated above, the conventional technique may degrade the high-frequency characteristics.

In view of this, the present disclosure provides a nitride semiconductor device having superior high-frequency characteristics, and a method for manufacturing the same.

### Solution to Problem

A nitride semiconductor device according to one aspect of the present disclosure is a nitride semiconductor device including an active element and a passive element, and includes: a nitride semiconductor layer divided into an active region and an inactive region in a plan view; and a metal layer in contact with the nitride semiconductor layer in the inactive region. The active element is provided in the active region. The passive element is provided in the inactive region. The metal layer includes a coherent state or a metamorphic state relative to the nitride semiconductor layer.

A method for manufacturing a nitride semiconductor device according to one aspect of the present disclosure is a method for manufacturing a nitride semiconductor device including an active element and a passive element, and includes: forming a nitride semiconductor layer that is divided into an active region and an inactive region in a plan view; and forming a metal layer that is in contact with the nitride semiconductor layer in the inactive region. The active element is provided in the active region. The passive element is provided in the inactive region. The metal layer includes a coherent state or a metamorphic state relative to the nitride semiconductor layer.

### Advantageous Effects

The present disclosure makes it possible to provide a nitride semiconductor device having superior high-frequency characteristics, and a method for manufacturing the same.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1A is a cross-sectional view of a nitride semiconductor device according to Embodiment 1 that includes a capacitor as a passive element.

FIG. 1B is a cross-sectional view of a nitride semiconductor device according to Embodiment 1 that includes a resistive element as a passive element.

FIG. 1C is a cross-sectional view of a nitride semiconductor device according to Embodiment 1 that includes an inductor as an active element.

FIG. 2A is a diagram showing a crystal structure of a hexagonal close-packed structure.

FIG. 2B is a diagram showing a crystal structure of a face-centered cubic lattice structure.

FIG. 3A is a cross-sectional view of a nitride semiconductor device according to Variation 1 of Embodiment 1 that includes a capacitor as a passive element.

FIG. 3B is a cross-sectional view of a nitride semiconductor device according to Variation 1 of Embodiment 1 that includes a resistive element as a passive element.

FIG. 3C is a cross-sectional view of a nitride semiconductor device according to Variation 1 of Embodiment 1 that includes an inductor as an active element.

FIG. 4A is a cross-sectional view of a nitride semiconductor device according to Variation 2 of Embodiment 1 that includes a capacitor as a passive element.

FIG. 4B is a cross-sectional view of a nitride semiconductor device according to Variation 2 of Embodiment 1 that includes a resistive element as a passive element.

FIG. 4C is a cross-sectional view of a nitride semiconductor device according to Variation 2 of Embodiment 1 that includes an inductor as an active element.

FIG. 5A is a cross-sectional view of a nitride semiconductor device according to Variation 3 of Embodiment 1 that includes a capacitor as a passive element.

FIG. 5B is a cross-sectional view of a nitride semiconductor device according to Variation 3 of Embodiment 1 that includes a resistive element as a passive element.

FIG. 5C is a cross-sectional view of a nitride semiconductor device according to Variation 3 of Embodiment 1 that includes an inductor as an active element.

FIG. 6 is a flow chart showing a first example of a method for manufacturing a nitride semiconductor device according to Embodiment 1.

FIG. 7A is a cross-sectional view for illustrating a process included in the first example of the method for manufacturing the nitride semiconductor device according to Embodiment 1.

FIG. 7B is a cross-sectional view for illustrating a process included in the first example of the method for manufacturing the nitride semiconductor device according to Embodiment 1.

FIG. 7C is a cross-sectional view for illustrating a process included in the first example of the method for manufacturing the nitride semiconductor device according to Embodiment 1.

FIG. 7D is a cross-sectional view for illustrating a process included in the first example of the method for manufacturing the nitride semiconductor device according to Embodiment 1.

FIG. 7E is a cross-sectional view for illustrating a process included in the first example of the method for manufacturing the nitride semiconductor device according to Embodiment 1.

FIG. 7F is a cross-sectional view for illustrating a process included in the first example of the method for manufacturing the nitride semiconductor device according to Embodiment 1.

FIG. 8 is a flow chart showing a second example of the method for manufacturing the nitride semiconductor device according to Embodiment 1.

FIG. 9A is a cross-sectional view for illustrating a process included in the second example of the method for manufacturing the nitride semiconductor device according to Embodiment 1.

FIG. 9B is a cross-sectional view for illustrating a process included in the second example of the method for manufacturing the nitride semiconductor device according to Embodiment 1.

FIG. 10 is a flow chart showing a third example of the method for manufacturing the nitride semiconductor device according to Embodiment 1.

FIG. 11 is cross-sectional view of a nitride semiconductor device according to Embodiment 2.

FIG. 12 is cross-sectional view of a nitride semiconductor device according to a variation of Embodiment 2.

### DESCRIPTION OF EMBODIMENTS

### Summary of the Present Disclosure

A nitride semiconductor device according to a first aspect of the present disclosure is a nitride semiconductor device including an active element and a passive element, and includes: a nitride semiconductor layer divided into an active region and an inactive region in a plan view; and a metal layer in contact with the nitride semiconductor layer in the inactive region. The active element is provided in the active region. The passive element is provided in the inactive region. The metal layer includes a coherent state or a metamorphic state relative to the nitride semiconductor layer.

Accordingly, since the crystallinity of the metal layer is improved, it is possible to improve high-frequency characteristics by improving the electrical characteristics of the metal layer (e.g., by decreasing resistance). In addition, since the metal layer is provided in the inactive region, the passive element including the metal layer becomes insusceptible to carrier fluctuations during high-frequency operation. As a result, it is possible to achieve the nitride semiconductor device having the superior high-frequency characteristics.

A nitride semiconductor device according to a second aspect of the present disclosure is the nitride semiconductor device according to the first aspect, in which the nitride semiconductor layer includes a channel layer and a barrier layer provided above the channel layer, and the active element contains a two-dimensional electron gas formed in a vicinity of an interface between the channel layer and the barrier layer.

Accordingly, by using the high electron mobility of the two-dimensional electron gas (2DEG), the active element is allowed to perform a high-speed operation. For example, it is possible to increase the speed of switching operation and thus improve the high-frequency characteristics of the nitride semiconductor device.

A nitride semiconductor device according to a third aspect of the present disclosure is the nitride semiconductor device according to the second aspect, in which the channel layer has a carrier concentration of at least 1×10¹⁵ cm⁻³ in the active region.

Accordingly, by using the high electron mobility of the 2DEG, the active element is allowed to perform a high-speed operation. For example, it is possible to increase the speed of switching operation and thus improve the high-frequency characteristics of the nitride semiconductor device.

A nitride semiconductor device according to a fourth aspect of the present disclosure is the nitride semiconductor device according to any one of the first aspect to the third aspect, in which the nitride semiconductor layer includes a layered structure including a plurality of layers, and an uppermost layer of the nitride semiconductor layer has a carrier concentration that is less than 1×10¹⁵ cm⁻³ in the inactive region.

Accordingly, since it is possible to reduce parasitic capacitance between the metal layer and the nitride semiconductor layer, the high-frequency characteristics of the passive element are improved.

A nitride semiconductor device according to a fifth aspect of the present disclosure is the nitride semiconductor device according to any one of the first aspect to the fourth aspect, in which a contact surface between the nitride semiconductor layer and the metal layer in the inactive region is located lower than an uppermost surface of the nitride semiconductor layer in the active region.

Accordingly, it is possible to prevent the 2DEG from forming in the inactive region by removing, for example, a large portion or all of the barrier layer. For this reason, since the carrier concentration of the nitride semiconductor layer is decreased, it is possible to reduce the parasitic capacitance between the metal layer and the nitride semiconductor layer. As a result, it is possible to improve the high-frequency characteristics of the passive element.

A nitride semiconductor device according to a sixth aspect of the present disclosure is the nitride semiconductor device according to one of the second aspect or the third aspect, in which the nitride semiconductor layer further includes a buffer layer provided below the channel layer, and the metal layer is in contact with the buffer layer in the inactive region.

Accordingly, the buffer layer is generally a high-resistance layer and has a sufficiently low carrier concentration. For this reason, since operation variation is reduced, it is possible to improve the high-frequency characteristics of the passive element.

A nitride semiconductor device according to a seventh aspect of the present disclosure is the nitride semiconductor device according to any one of the first aspect to the sixth aspect, in which the nitride semiconductor layer includes an impurity region doped with C or Fe, and the metal layer is in contact with the impurity region in the inactive region.

Accordingly, the resistance of the impurity region doped with C or Fe is increased. For this reason, since operation variation is reduced, it is possible to improve the high-frequency characteristics of the passive element.

A nitride semiconductor device according to an eighth aspect of the present disclosure is the nitride semiconductor device according to any one of the first aspect to the seventh aspect, in which the metal layer includes: a barrier metal layer; and a low-resistance metal layer located above the barrier metal layer and having a resistance lower than a resistance of the barrier metal layer.

Accordingly, mixed crystals between the low-resistance metal layer and the nitride semiconductor layer are reduced. Since the generation of carriers in the nitride semiconductor layer is inhibited, the passive element becomes insusceptible to the carrier fluctuations. As a result, it is possible to improve the high-frequency characteristics of the passive element.

A nitride semiconductor device according to a ninth aspect of the present disclosure is the nitride semiconductor device according to any one of the first aspect to the eighth aspect, in which the passive element is a resistive element including the metal layer.

Accordingly, since the crystallinity of the metal layer is improved, resistance to electro migration is increased. Since the occurrence of break or short circuit of the resistive element is reduced, it is possible to improve the high-frequency characteristics of the resistive element.

A nitride semiconductor device according to a tenth aspect of the present disclosure is the nitride semiconductor device according to any one of the first aspect to the eighth aspect, in which the passive element is a capacitor including the metal layer as a lower electrode.

Accordingly, since the crystallinity of the metal layer that is the lower electrode is improved, a decrease in resistance of the lower electrode is achieved, and it is possible to reduce loss due to parasitic resistance components. Additionally, since abnormal growth such as hillocks is inhibited, it is possible to mitigate a decrease in coverage with an insulating layer and electric field crowding. As a result, it is possible to mitigate a decrease in breakdown voltage of the capacitor.

A nitride semiconductor device according to a tenth aspect of the present disclosure is the nitride semiconductor device according to any one of the first aspect to the eighth aspect, in which the passive element is an inductor including the metal layer.

Accordingly, since the crystallinity of the metal layer is improved, it is possible to reduce the parasitic resistance components of the inductor. Accordingly, it is possible to reduce loss due to the parasitic resistance components.

A nitride semiconductor device according to a twelfth aspect of the present disclosure is the nitride semiconductor device according to the eighth aspect, in which the barrier metal layer has a lattice constant that is larger than a lattice constant of the low-resistance metal layer and is less than or equal to √2 times a lattice constant of the nitride semiconductor layer along an a-axis in the contact surface with the metal layer.

Accordingly, since it is possible to reduce dislocations that can occur in the low-resistance metal layer, it is possible to further decrease the resistance of the low-resistance metal layer.

A nitride semiconductor device according to a thirteenth aspect of the present disclosure is the nitride semiconductor device according to the twelfth aspect, in which the low-resistance metal layer and the barrier metal layer each have a lattice constant that is at least 90% of √2 times the lattice constant of the nitride semiconductor layer along the a-axis in the contact surface with the metal layer.

Accordingly, since it is possible to reduce the dislocations that can occur in the low-resistance metal layer, it is possible to further decrease the resistance of the low-resistance metal layer.

A nitride semiconductor device according to a fourteenth aspect of the present disclosure is the nitride semiconductor device according to the eighth aspect, the twelfth aspect, or the thirteenth aspect, in which the low-resistance metal layer includes a face-centered cubic lattice structure including at least one element selected from a group consisting of Al, Cu, Au, Ag, and Pt.

Accordingly, it is possible to decrease the resistance of the metal layer while maintaining the crystallinity of the metal layer.

A nitride semiconductor device according to a fifteenth aspect of the present disclosure is the nitride semiconductor device according to any one of the eighth aspect and the twelfth aspect to the fourteenth aspect, in which the barrier metal layer includes an NaCl-type structure including: at least one element selected from a group consisting of Ti, Ta, W, and Hf; and an element including at least one of N or C.

Accordingly, it is possible to reduce the mixed crystals between the metal layer and the nitride semiconductor layer while maintaining the crystallinity of the metal layer.

A nitride semiconductor device according to a sixteenth aspect of the present disclosure is the nitride semiconductor device according to any one of the eighth aspect and the twelfth aspect to the fifteenth aspect, in which the metal layer further includes a layer that is provided between the barrier metal layer and the nitride semiconductor layer, the layer including a hexagonal close-packed structure including at least one element selected from a group consisting of Ti, Ta, W, and Hf.

Accordingly, it is possible to increase adhesiveness between the metal layer and the nitride semiconductor layer while maintaining the crystallinity of the metal layer.

A nitride semiconductor device according to a seventeenth aspect of the present disclosure is the nitride semiconductor device according to any one of the first aspect to the sixteenth aspect, in which the active element includes a gate electrode, a source electrode, and a drain electrode, and at least one of the gate electrode, the source electrode, or the drain electrode includes a material identical to a material of at least a portion of the metal layer.

Accordingly, it is possible to from the electrode including the same material as the metal layer in the same process as the metal layer.

A method for manufacturing a nitride semiconductor device according to an eighteenth aspect of the present disclosure is a method for manufacturing a nitride semiconductor device including an active element and a passive element, and includes: forming a nitride semiconductor layer that is divided into an active region and an inactive region in a plan view; and forming a metal layer that is in contact with the nitride semiconductor layer in the inactive region. The active element is provided in the active region. The passive element is provided in the inactive region. The metal layer includes a coherent state or a metamorphic state relative to the nitride semiconductor layer.

Accordingly, it is possible to form the metal layer having superior crystallinity, and improve high-frequency characteristics by improving the electrical characteristics of the metal layer (e.g., by decreasing resistance). In addition, since the metal layer is provided in the inactive region, the passive element including the metal layer becomes insusceptible to carrier fluctuations during high-frequency operation. As a result, it is possible to manufacture the nitride semiconductor device having superior high-frequency characteristics.

A method for manufacturing a nitride semiconductor device according to an nineteenth aspect of the present disclosure is the method for manufacturing the nitride semiconductor device according to the eighteenth aspect of the present disclosure, and includes: forming a first recessed portion in the nitride semiconductor layer; forming a source electrode and a drain electrode of the active element in the first recessed portion; forming a gate electrode of the active element on the nitride semiconductor layer; and forming a second recessed portion in the nitride semiconductor layer before forming the metal layer. In the forming of the metal layer, the metal layer is formed in a bottom surface of the second recessed portion.

Accordingly, the second recessed portion makes it possible to easily inactivate the nitride semiconductor layer.

A method for manufacturing a nitride semiconductor device according to a twentieth aspect of the present disclosure is the method for manufacturing the nitride semiconductor device according to the nineteenth aspect of the present disclosure, in which the forming of the first recessed portion and the forming of the second recessed portion are performed simultaneously.

Accordingly, it is possible to from the first recessed portion and the second recessed portion in the same process. Simplifying the manufacturing process makes it possible to reduce the chance of manufacturing errors etc. and increase yields.

A method for manufacturing a nitride semiconductor device according to a twenty-first aspect of the present disclosure is the method for manufacturing the nitride semiconductor device according to the nineteenth aspect or the twentieth aspect, in which the forming of the metal layer and the forming of the gate electrode are performed simultaneously.

Accordingly, it is possible to form the metal layer and the gate electrode in the same process. Simplifying the manufacturing process makes it possible to reduce the chance of manufacturing errors etc. and increase yields.

A method for manufacturing a nitride semiconductor device according to a twenty-second aspect of the present disclosure is the method for manufacturing the nitride semiconductor device according to the twenty-first aspect or the twentieth aspect, in which the passive element is a capacitor including the metal layer as a lower electrode, and the method for manufacturing the nitride semiconductor device further includes: forming an insulating layer on the metal layer; and forming an upper electrode on the insulating layer.

Accordingly, since the crystallinity of the metal layer that is the lower electrode is improved, a decrease in resistance of the lower electrode is achieved, and it is possible to reduce loss due to parasitic resistance components. Additionally, since abnormal growth such as hillocks is inhibited, it is possible to mitigate a decrease in coverage with the insulating layer and electric field crowding. As a result, it is possible to mitigate a decrease in breakdown voltage of the capacitor.

Hereinafter, embodiments are specifically described with reference to the Drawings.

It should be noted that the embodiments described below each show a general or specific example. The numerical values, shapes, materials, constituent elements, the arrangement and connection of the constituent elements, manufacturing processes, the order of manufacturing processes, etc. shown in the following embodiments are mere examples, and do not intend to limit the present disclosure. Moreover, among the constituent elements described in the following embodiments, those not recited in the independent claims are described as optional constituent elements.

Furthermore, the figures are schematic illustrations and are not necessarily precise depictions. Accordingly, for example, the figures are not necessarily to scale. Moreover, substantially the same constituent elements are assigned the same reference signs in the figures, and overlapping descriptions are omitted or simplified. Furthermore, in the Specification, terms indicating relationships between element such as parallel or perpendicular, terms indicating the shapes of elements, and numerical ranges are not expressions indicating only strict meanings but expressions intended to include substantially equivalent ranges, that is, differences of approximately several percent, for example.

Moreover, in the Specification and the figures, an x axis, an y axis, and a z axis indicate three axes in a three-dimensional orthogonal coordinate system. In each of the embodiments, a direction perpendicular to the principal surface of a substrate is defined as a z-axis direction, and directions parallel to the principal surface of the substrate are defined as an x-axis direction and a y-axis direction.

It should be noted that in the Specification, the “principal surface” of a substrate is a major surface of the substrate and means, for example, a surface having the largest area or a surface that is opposite the surface having the largest area and has the same area as the surface having the largest area. The principal surface is generally a flat surface, but may include minute irregularities or a curve. The same applies to the “principal surface” of each of layers such as a semiconductor layer, a metal layer, or an insulating layer. Furthermore, in the Specification, the terms “above” and “below” do not refer to the vertically upward direction and the vertically downward direction in terms of absolute space recognition, but are used as terms defined by relative positional relationships based on the layering order in a layered configuration. Specifically, the positive direction of the z axis is regarded as “above”, and the negative direction of the z axis is regarded as “below”. Additionally, the terms “above” and “below” are applied not only when two constituent elements are disposed spaced apart from each other to have another constituent element interposed therebetween but also when two constituent elements are disposed in close contact with each other.

Moreover, in the Specification, unless otherwise noted, a “plan view” means a view from a direction perpendicular to the principal surface of the substrate. Specifically, the “plan view” means a view from the positive side or the negative side of the z axis.

Furthermore, a layer including one or more elements or compositions and a layer configured with one or more elements or compositions each mean that the layer substantially includes only one or more elements or compositions. However, the layer may include, as impurities, another element such as an element inevitably mixed during manufacturing, at a rate of at most 1%.

Moreover, in the Specification, unless otherwise noted, ordinal numbers such as “first” and “second” do not mean the number or order of constituent elements, and are used to avoid confusion among constituent elements of the same type and distinguish one from the other.

### Embodiment 1

First, a nitride semiconductor device according to Embodiment 1 is described.

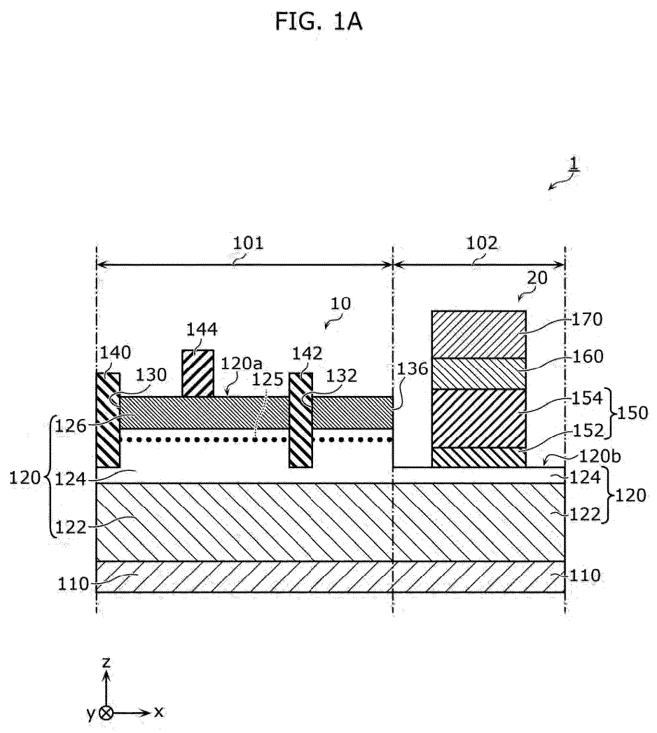

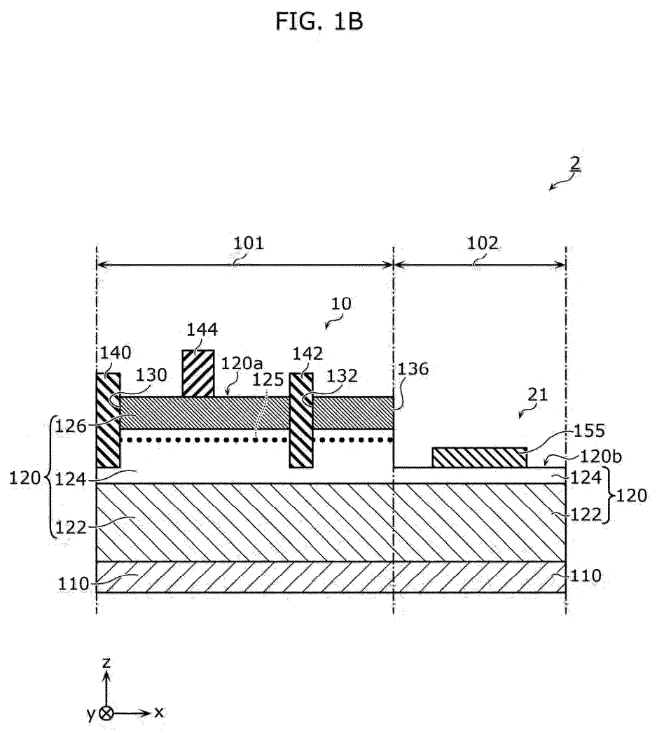

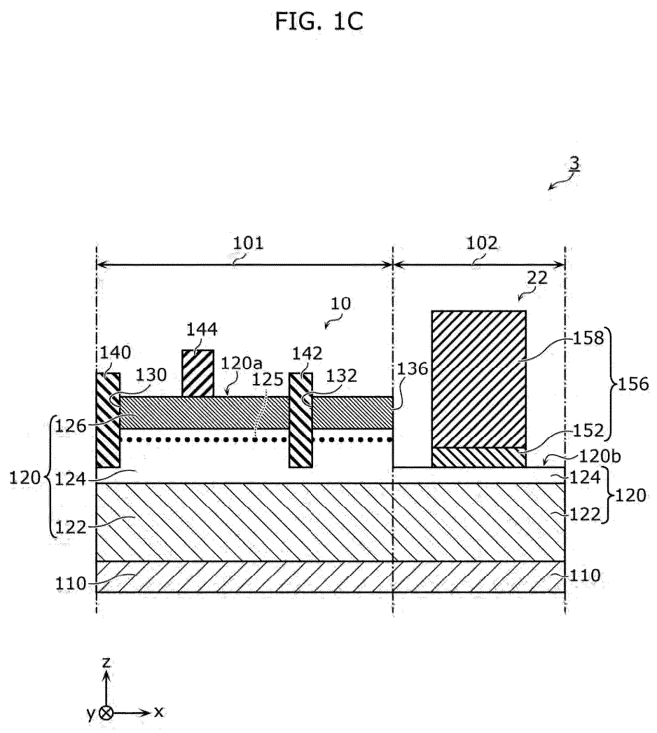

The nitride semiconductor device according to the present embodiment includes an active element and a passive element. The active element is, for example, a transistor or a tunnel diode. The passive element is, for example, a capacitor, a resistive element, or an inductor. Hereinafter, first, a nitride semiconductor device including a capacitor as a passive element is described with reference to FIG. 1A. A configuration including a resistive element or an inductor is described later with reference to FIG. 1B or FIG. 1C. [Nitride Semiconductor Device Including Capacitor] FIG. 1A is a cross-sectional view of nitride semiconductor device 1 according to the present embodiment that includes capacitor as a passive element. As shown in FIG. 1A, nitride semiconductor device 1 includes transistor 10 and capacitor 20. Additionally, nitride semiconductor device 1 includes substrate 110 and nitride semiconductor layer 120.

Transistor 10 is an example of an active element and is provided in active region 101. Capacitor 20 is an example of a passive element and is provided in inactive region 102.

Active region 101 and inactive region 102 are regions that do not overlap each other in a plan view. In the present embodiment, active region 101 and inactive region 102 are separated depending on the presence or absence of second recessed portion 136. Specifically, a region in which second recessed portion 136 is provided is inactive region 102, and a region in which second recessed portion 136 is not provided is active region 101. In active region 101, channel layer 124 has a carrier concentration of at least 1×10¹⁵ cm⁻³. In inactive region 102, channel layer 124 has a carrier concentration less than 1×10¹⁵ cm⁻³.

As shown in FIG. 1A, transistor 10 includes a portion of each of substrate 110 and nitride semiconductor layer 120 located in active region 101, source electrode 140, drain electrode 142, and gate electrode 144. In the portion of nitride semiconductor layer 120 located in active region 101, two-dimensional electron gas (2DEG) 125 forms in the vicinity of an interface between channel layer 124 and barrier layer 126. Transistor 10 is a high-electron-mobility transistor (HEMT) containing 2DEG 125 as a channel.

Substrate 110 is a base substrate for forming nitride semiconductor layer 120. Substrate 110 is, for example, an Si single crystal substrate including a principal plane (upper plane) that is the (111) plane. For example, substrate 110 has a resistivity of at least 1 kΩcm, but the present embodiment is not limited to this example. Substrate 110 may have a resistivity of at most 20 Ωcm. Additionally, substrate 110 is not limited to the Si single crystal substrate, and may be a substrate including, for example, SiC, sapphire, GaN, or AlN.

Nitride semiconductor layer 120 is a layer including a group-III nitride semiconductor. Nitride semiconductor layer 120 includes a layered structure having a plurality of layers. Specifically, as shown in FIG. 1A, nitride semiconductor layer 120 includes buffer layer 122, channel layer 124, and barrier layer 126.

Nitride semiconductor layer 120 is divided into active region 101 and inactive region 102 in the plan view. In the present embodiment, buffer layer 122 includes the same configuration between active region 101 and inactive region 102. A portion of channel layer 124 located in active region 101 is thicker than a portion of channel layer 124 located in inactive region 102. Barrier layer 126 is provided in active region 101 and is not provided in inactive region 102.

Buffer layer 122 is provided above substrate 110 and below channel layer 124. Specifically, buffer layer 122 is provided in contact with each of the upper surface of substrate 110 and the lower surface of channel layer 124. Buffer layer 122 is a layer including a group-III nitride semiconductor. For example, buffer layer 122 includes a layered structure having a plurality of layers each including undoped AlₓGa₁₋ₓN. Here, x is at least 0 and at most 1. In other words, buffer layer 122 may include an AlN layer or a GaN layer. Buffer layer 122 may include a layer the resistance of which is increased by being doped with C or Fe. Additionally, buffer layer 122 may include a superlattice structure. It should be noted that buffer layer 122 may include a single-layer structure of a GaN layer, an AlGaN layer, or an AlN layer. Alternatively, buffer layer 122 need not be provided.

Channel layer 124 is provided above substrate 110. Specifically, channel layer 124 is provided in contact with the upper surface of buffer layer 122. Channel layer 124 is a layer including a group-III nitride semiconductor. For example, although channel layer 124 is a layer including GaN, channel layer 124 may include In.

In the present embodiment, channel layer 124 differs in thickness between active region 101 and inactive region 102. Specifically, channel layer 124 in active region 101 is thicker than channel layer 124 in inactive region 102. Channel layer 124 in active region 101 has, for example, a thickness of 150 nm. Although the thickness of channel layer 124 in inactive region 102 is, for example, less than or equal to half of the thickness of channel layer 124 in active region 101, the thickness of channel layer 124 in inactive region 102 may be less than or equal to 10% of the thickness of channel layer 124 in active region 101. However, the present embodiment is not limited to this example. Channel layer 124 in inactive region 102 is formed to have a thickness that causes the upper surface (i.e., the bottom surface of second recessed portion 136, contact surface 120b shown in FIG. 1A) of channel layer 124 in inactive region 102 to be located below 2DEG 125 that forms in active region 101. It should be noted that channel layer 124 may have a uniform thickness between active region 101 and inactive region 102.

Barrier layer 126 is provided above channel layer 124. For example, barrier layer 126 is provided in contact with the upper surface of channel layer 124. Barrier layer 126 is a layer including a group-III nitride semiconductor. For example, barrier layer 126 is a layer having a thickness of 13 nm and including Al_{0.25}Ga_{0.75}N, but the present embodiment is not limited to this example. An Al composition ratio in AlGaN included in barrier layer 126 may be a value selected from a range from 15% to 100%, inclusive. Additionally, barrier layer 126 may include In.

Barrier layer 126 has a band gap larger than the band gap of channel layer 124. 2DEG 125 forms in the vicinity of the interface between barrier layer 126 and channel layer 124. In the present embodiment, since barrier layer 126 is not provided in inactive region 102 and is provided only in active region 101, 2DEG 125 does not form in inactive region 102 and forms only in active region 101. 2DEG 125 that forms in active region 101 functions as a channel of transistor 10. In active region 101, channel layer 124 has a carrier concentration of at least 1×10¹⁵ cm-3 at room temperature. It should be noted that the room temperature is, for example, 25° C.

First recessed portions 130 and 132 and second recessed portion 136 are provided in nitride semiconductor layer 120. Each of first recessed portions 130 and 132 and second recessed portion 136 is a recessed portion that is obtained by removing at least a portion of channel layer 124 and penetrates through barrier 126.

First recessed portion 130 is provided to reduce contact resistance between source electrode 140 and 2DEG 125. 2DEG 125 is exposed on the inner surface of first recessed portion 130, and it is possible to reduce the contact resistance by source electrode 140 coming directly into contact with exposed 2DEG 125.

First recessed portion 132 is provided to reduce contact resistance between drain electrode 142 and 2DEG 125. 2DEG 125 is exposed on the inner surface of first recessed portion 132, and it is possible to reduce the contact resistance by drain electrode 142 coming directly into contact with exposed 2DEG 125.

The bottom surface of each of first recessed portions 130 and 132 is located below the interface between channel layer 124 and barrier layer 126. A difference between the bottom surface of each of first recessed portions 130 and 132 and the interface between channel layer 124 and barrier layer 126 in the z-axis direction is at most 10 nm.

Second recessed portion 136 is provided to inactivate nitride semiconductor layer 120. The bottom surface (contact surface 120b) of second recessed portion 136 is located below uppermost surface 120a of nitride semiconductor layer 120 in active region 101. Specifically, barrier layer 126 is removed in inactive region 102 by second recessed portion 136 being provided. In inactive region 102, channel layer 124 is the uppermost layer of nitride semiconductor layer 120. As a result, it is possible to prevent 2DEG 125 from forming in channel layer 124, and the carrier concentration of channel layer 124 in inactive region 102 becomes less than 1×10¹⁵ cm-3 at room temperature. It should be noted that the room temperature is, for example, 25° C.

Source electrode 140 and drain electrode 142 are provided at distant positions to have gate electrode 144 interposed therebetween in the plan view. Each of source electrode 140 and drain electrode 142 is electrically connected to 2DEG 125. Specifically, source electrode 140 is provided in first recessed portion 130 to be in contact with 2DEG 125. Drain electrode 142 is provided in first recessed portion 132 to be in contact with 2DEG 125.

Each of source electrode 140 and drain electrode 142 is formed using a metal material that is in ohmic contact with an n-type nitride semiconductor. For example, each of source electrode 140 and drain electrode 142 is a multilayer electrode film including a layered structure having a Ti film having a thickness of 30 nm and an Al film provided on the Ti film and having a thickness of 200 nm.

It should be noted that the Ti film may have a thickness of at least 2 nm and at most 40 nm, and the Al film may have a thickness of at least 100 nm and at most 200 nm. Moreover, source electrode 140 and drain electrode 142 may each include a single metal element selected from a group consisting of Ti, Ta, Hf, Zr, Ru, Al, Au, and W or an alloy of a plurality of elements selected from the group. Furthermore, source electrode 140 and drain electrode 142 may each include a conductive metal nitride film such as TIN, WN, or TaN. Source electrode 140 and drain electrode 142 are formed in the same process, but source electrode 140 and drain electrode 142 may each be formed using a different material in a different process.

Gate electrode 144 is provided between source electrode 140 and drain electrode 142 in the plan view. In the present embodiment, gate electrode 144 is provided in contact with uppermost surface 120a of nitride semiconductor layer 120.

Gate electrode 144 is formed using a metal material that is in Schottky contact with nitride semiconductor layer 120. For example, gate electrode 144 is a multilayer electrode film including a layered structure having a TiN film and an Al film provided on the TiN film. The TIN film and the Al film are the same as barrier metal layer 152 and low-resistance metal layer 154 of capacitor 20, respectively. Gate electrode 144 may be formed using one element selected from a group consisting WN, TaN, HfN, Ni, Ti, Ta, W, Au, Pd, Pt, Hf, Ru, and Cu.

It should be noted that an insulating layer or a p-type nitride semiconductor layer may be provided between gate electrode 144 and uppermost surface 120a of nitride semiconductor layer 120. The insulating layer includes a single layer or a layered structure such as SIN, SiO₂, SION, or Al₂O₃. The p-type nitride semiconductor layer is, for example, p-type GaN or AlGaN. When the p-type nitride semiconductor layer is provided, gate electrode 144 may be in ohmic contact with the p-type nitride semiconductor layer.

Next, capacitor 20 is described. As shown in FIG. 1A, capacitor 20 includes lower electrode 150, insulating layer 160, and upper electrode 170.

Lower electrode 150 is an example of a metal layer in contact with nitride semiconductor layer 120 in inactive region 102. Lower electrode 150 includes a coherent state or a metamorphic state relative to nitride semiconductor layer 120. The coherent state and the metamorphic state are described later. In the present embodiment, lower electrode 150 includes barrier metal layer 152 and low-resistance metal layer 154.

Barrier metal layer 152 is provided to reduce the diffusion of a metal element (e.g., Cu) included in low-resistance metal layer 154 into nitride semiconductor layer 120. Barrier metal layer 152 is in contact with nitride semiconductor layer 120 in inactive region 102. Specifically, barrier metal layer 152 is in contact with contact surface 120b that is the bottom surface of second recessed portion 136 and a portion of the surface of channel layer 124.

Barrier metal layer 152 includes an NaCl-type structure including: at least one element selected from a group consisting of Ti, Ta, W, and Hf; and an element including at least one of N or C. For example, although barrier metal layer 152 is a single-layer film including one compound selected from a group consisting of TIN, TaN, WN, HIN, TiC, and TaC, barrier metal layer 152 may be a layered film. Barrier metal layer 152 has, for example, a thickness of at least 5 nm and at most 200 nm, and has a thickness of 20 nm as an example. However, the present embodiment is not limited to this example.

Low-resistance metal layer 154 is provided above barrier metal layer 152. Specifically, low-resistance metal layer 154 is provided in contact with the upper surface of barrier metal layer 152. Low-resistance metal layer 154 has a resistance lower than the resistance of barrier metal layer 152. It is possible to reduce a parasitic resistance of lower electrode 150 by low-resistance metal layer 154 including lower electrode 150.

Low-resistance metal layer 154 includes a face-centered cubic (fcc) lattice structure including at least one element selected from a group consisting of Al, Cu, Au, Ag, and Pt. For example, although low-resistance metal layer 154 is a single-layer film including one element selected from the group consisting of Al, Cu, Au, Ag, and Pt, low-resistance metal layer 154 may be a layered film. Low-resistance metal layer 154 is thicker than barrier metal layer 152, has, for example, a thickness of at least 100 nm and at most 1000 nm, and has a thickness of 500 nm as an example. However, the present embodiment is not limited to this example.

Insulating layer 160 is provided between lower electrode 150 and upper electrode 170. Insulating layer 160 is formed using a film having a high permittivity and a high insulation breakdown electric field. For example, although insulating layer 160 is a single-layer film including one compound selected from a group consisting of SIN, AlN, HAN, HfO, and Ta₂O₅, insulating layer 160 may be a layered film. The thickness of insulating layer 160 is not particularly limited, and is a thickness determined based on a capacitance value or a breakdown voltage required of capacitor 20.

Upper electrode 170 is provided above insulating layer 160. Although upper electrode 170 is a single-layer film including at least one element selected from a group consisting of Al, Cu, Au, Ag, and Pt, upper electrode 170 may be a layered film.

As stated above, since lower electrode 150 is provided in inactive region 102 in nitride semiconductor device 1 according to the present embodiment, nitride semiconductor device 1 is insusceptible to carrier fluctuations during high-frequency operation. Accordingly, it is possible to achieve capacitor 20 having superior high-frequency characteristics.

Moreover, lower electrode 150 included in capacitor 20 includes the coherent state or the metamorphic state relative to nitride semiconductor layer 120. As a result, the crystallinity of lower electrode 150 increases, and the high-frequency characteristics of capacitor 20 improve. In what follows, the coherent state and the metamorphic state are described.

The coherent state is a state in which a layer holds crystal information about an underlayer due to lattice distortion in the layer. The metamorphic state is a state in which a layer as a whole holds crystal information about an underlayer by introducing defects into the layer. In other words, in each of the coherent state and the metamorphic state, a layer (lower electrode 150 (barrier metal layer 152)) holds crystal information about an underlayer (nitride semiconductor layer 120 (channel layer 124)).

Each of barrier metal layer 152 and low-resistance metal layer 154 is in the coherent state or the metamorphic state relative to channel layer 124. To achieve the coherent state or the metamorphic states, a crystal structure and a lattice constant are required to satisfy predetermined conditions.

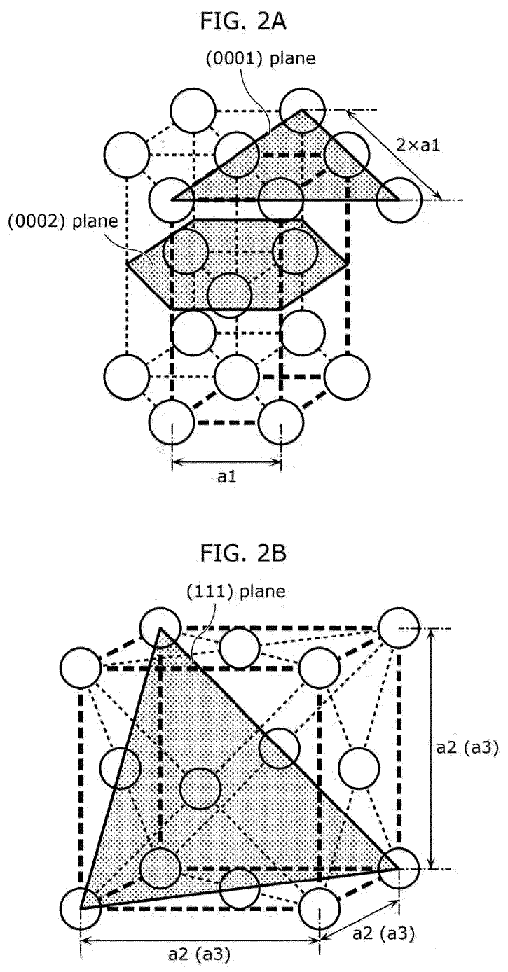

A crystal structure of channel layer 124 that is the underlayer is a hexagonal close-packed (hcp) structure shown in FIG. 2A. It should be noted that FIG. 2A is a diagram showing a crystal structure of the hexagonal close-packed (hcp) structure. FIG. 2B is a diagram showing a crystal structure of a face-centered cubic (fcc) lattice structure.

A crystal structure that is in the coherent state or the metamorphic state relative to the hcp structure is the fcc structure or the NaCl structure. In the present embodiment, barrier metal layer 152 includes the NaCl structure, and low-resistance metal layer 154 includes the fcc structure shown in FIG. 2B. It is possible to regard the NaCl structure as substantially the same as the fcc structure shown in FIG. 2B.

The (111) plane that is one of the crystal planes of barrier metal layer 152 parallels and is co-oriented with the (0002) plane that is one of the crystal planes of channel layer 124. In addition, the (111) plane that is one of the crystal planes of low-resistance metal layer 154 parallels and is co-oriented with the (0002) plane that is one of the crystal planes of channel layer 124. Both barrier metal layer 152 and low-resistance metal layer 154 are oriented toward only the (111) plane.

Specifically, barrier metal layer 152 and low-resistance metal layer 154 are formed to cause six elements located at the vertices and midpoints of the respective sides of a triangle (a region shaded with dots) in the (111) plane shown in FIG. 2B to correspond to six elements shown in FIG. 2A. It should be noted that in FIG. 2A, the six elements are represented using the (0001) plane instead of the (0002) plane. In this case, a lattice constant satisfies the following relationship.

Barrier metal layer 152 has a lattice constant that is larger than the lattice constant of low-resistance metal layer 154, and is less than or equal to √2 times the lattice constant of nitride semiconductor layer 120 along the a-axis in contact surface 120b with lower electrode 150. To put it another way, the following inequality (1) is satisfied, where the lattice constant of channel layer 124 along the a-axis is denoted by “a1”, the lattice constant of barrier metal layer 152 is denoted by “a2”, and the lattice constant of low-resistance metal layer 154 is denoted by “a3”.

$$a 1 \times √ 2 \geq a 2 > a 3 \qquad ( 1 )$$

It should be noted that √2 denotes the square root of two (1.4142 . . . ).

As stated above, it is possible to reduce the occurrence of dislocations in low-resistance metal layer 154 by decreasing the lattice constant of barrier metal layer 152, and subsequently decreasing the lattice constant of low-resistance metal layer 154 below the lattice constant of barrier metal layer 152, with reference to the lattice constant of nitride semiconductor layer 120 (channel layer 124) along the a-axis multiplied by √2. Accordingly, it is possible to decrease the resistance of lower electrode 150.

Additionally, lattice constant a3 of low-resistance metal layer 154 and lattice constant a2 of barrier metal layer 152 may be at least 90% of √2 times lattice constant a1 of channel layer 124 along the a-axis in contact surface 120b. In other words, the lattice constant of each of the layers may further satisfy the following inequalities (2) and (3).

$$a 3 \geq a 1 \times √ 2 \times 0.9 \qquad ( 2 )$$

$$a 2 \geq a 1 \times √ 2 \times 0.9 \qquad ( 3 )$$

To put it another way, a difference between the lattice constant of channel layer 124 multiplied by √2 and the lattice constant of barrier metal layer 152 or low-resistance metal layer 154 is within ±10%. The crystallinity of each of barrier metal layer 152 and low-resistance metal layer 154 further increases by satisfying such a relationship. A further decrease in the resistance of low-resistance metal layer 154 is achieved by the dislocations included in low-resistance metal layer 154 being reduced. Moreover, it is possible to reduce loss due to parasitic resistance components by decreasing the resistance of lower electrode 150. Furthermore, since abnormal growth such as hillocks is inhibited, it is possible to mitigate a decrease in coverage with insulating layer 160 and electric field crowding. Accordingly, it is possible to mitigate a decrease in breakdown voltage of capacitor 20.

Moreover, in the present embodiment, since barrier metal layer 152 is provided, mixed crystals between low-resistance metal layer 154 and channel layer 124 are reduced. Since this inhibits the generation of carriers in channel layer 124, capacitor 20 becomes insusceptible to the carrier fluctuations during operation. Accordingly, it is possible to improve the high-frequency characteristics of capacitor 20.

### [Nitride Semiconductor Device Including Resistive Element]

Next, a nitride semiconductor device including a resistive element as a passive element is described with reference to FIG. 1B. FIG. 1B is a cross-sectional view of nitride semiconductor device 2 including resistive element 21 as a passive element. As shown in FIG. 1B, nitride semiconductor device 2 includes transistor 10 and resistive element 21. Transistor 10 is identical to transistor 10 included in nitride semiconductor device 1 shown in FIG. 1A. Hereinafter, the differences from nitride semiconductor device 1 are mainly described, and the description of common points is omitted or simplified.

Resistive element 21 shown in FIG. 1B includes metal layer 155. Metal layer 155 is in contact with nitride semiconductor layer 120 in inactive region 102. Metal layer 155 includes the coherent state or the metamorphic state relative to nitride semiconductor layer 120. It is possible to form metal layer 155 using, for example, the same material as barrier metal layer 152. Alternatively, metal layer 155 may be formed using the same material as low-resistance metal layer 154. It is possible to form resistive element 21 having a desired resistance value by adjusting, for example, the thickness, material, and line width of metal layer 155.

As with lower electrode 150 of nitride semiconductor device 1, nitride semiconductor device 2 improves the crystallinity of metal layer 155. For this reason, the resistance of metal layer 155 to electromigration is improved. Accordingly, since the occurrence of break or short circuit of resistive element 21 is reduced, it is possible to improve the high-frequency characteristics of resistive element 21.

### [Nitride Semiconductor Device Including Inductor]

Then, a nitride semiconductor device including an inductor as a passive element is described with reference to FIG. 1C. FIG. 1C is a cross-sectional view of nitride semiconductor device 3 including inductor 22 as a passive element. As shown in FIG. 1C, nitride semiconductor device 3 includes transistor 10 and inductor 22.

Transistor 10 is identical to transistor 10 included in nitride semiconductor device 1 shown in FIG. 1A. Hereinafter, the differences from nitride semiconductor device 1 are mainly described, and the description of common points is omitted or simplified.

Inductor 22 shown in FIG. 1C includes metal layer 156. Metal layer 156 is in contact with nitride semiconductor layer 120 in inactive region 102. Metal layer 156 includes the coherent state or the metamorphic state relative to nitride semiconductor layer 120. In the present embodiment, metal layer 156 includes barrier metal layer 152 and low-resistance metal layer 158.

Barrier metal layer 152 is identical to barrier metal layer 152 included in nitride semiconductor device 1 shown in FIG. 1A. Low-resistance metal layer 158 is substantially identical to low-resistance metal layer 154 included in nitride semiconductor device 1 shown in FIG. 1A, and differs from low-resistance metal layer 154 in thickness. Specifically, low-resistance metal layer 158 is thicker than low-resistance metal layer 154. For example, low-resistance metal layer 158 has both a thickness and a width of at least 3 μm. Accordingly, it is possible to further decrease the resistance of metal layer 156.

Inductor 22 is extended over a constant distance on contact surface 120b of inactive region 102. For example, inductor 22 may be provided in a linear manner or in a coil shape in the plan view.

As with lower electrode 150 of nitride semiconductor device 1, nitride semiconductor device 3 improves the crystallinity of metal layer 156. Since the crystallinity of metal layer 156 is improved, it is possible to reduce the parasitic resistance components of inductor 22. Accordingly, it is possible to reduce loss due to the parasitic resistance components.

### Variations

Subsequently, a plurality of variations of Embodiment 1 are described. In the variations described below, the differences from nitride semiconductor devices 1, 2, and 3 according to Embodiment 1 are mainly described, and the description of common points is omitted or simplified.

### Variation 1

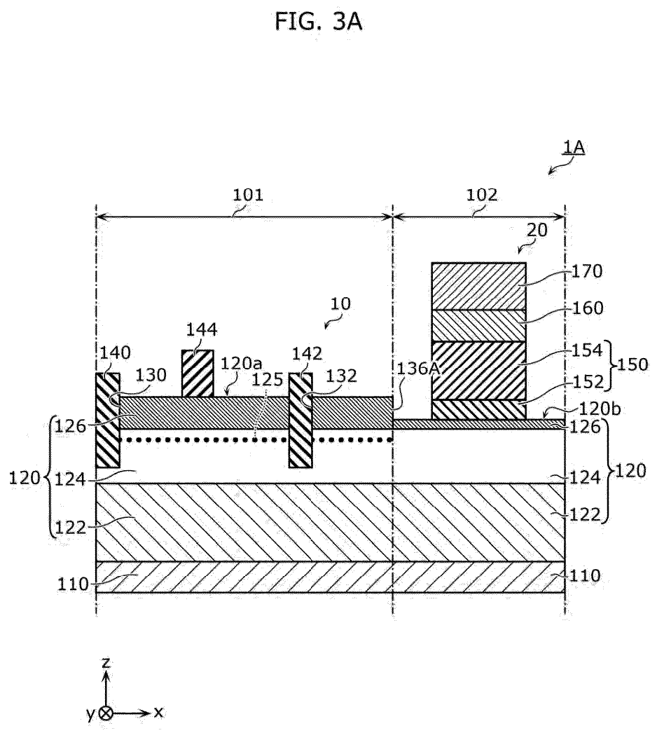

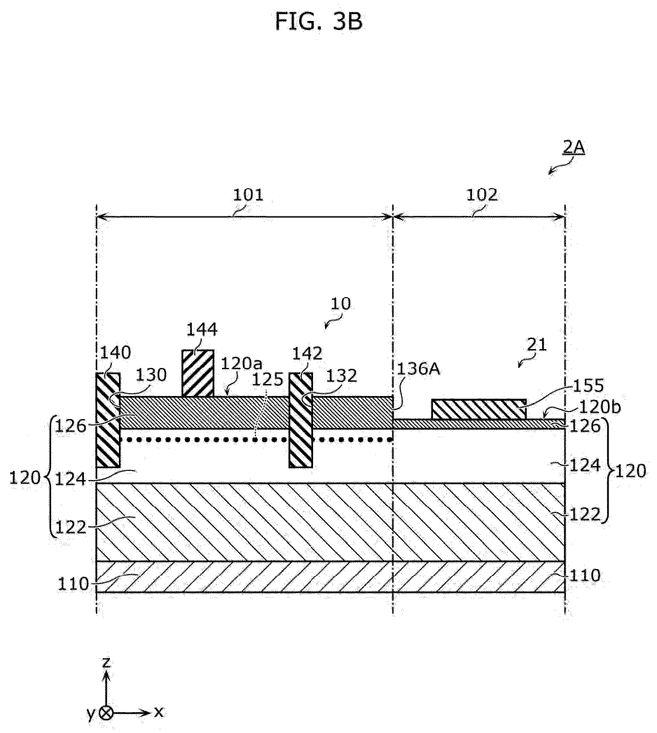

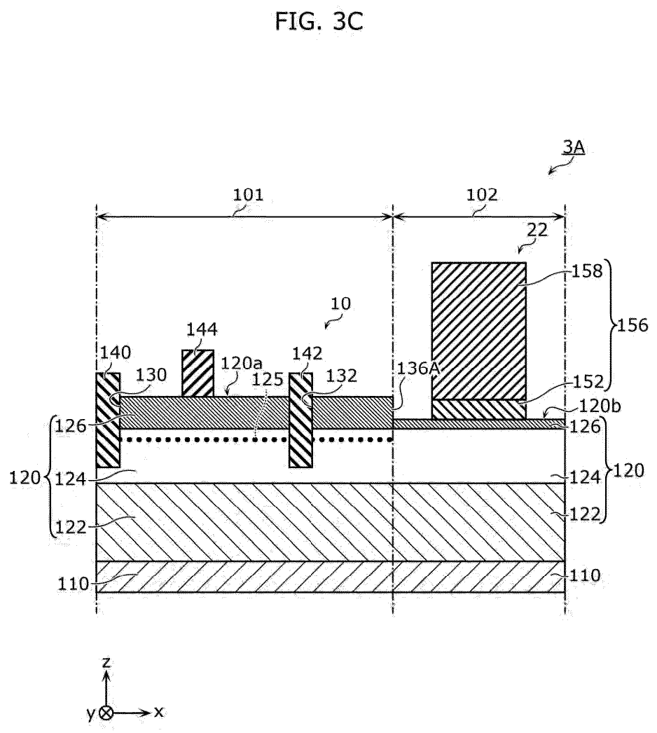

FIG. 3A is a cross-sectional view of nitride semiconductor device 1A according to the present variation that includes capacitor as a passive element. As shown in FIG. 3A, nitride semiconductor device 1A differs from nitride semiconductor device 1 in that second recessed portion 136A is provided instead of second recessed portion 136.

Second recessed portion 136A is provided to inactivate nitride semiconductor layer 120. The bottom surface (contact surface 120b) of second recessed portion 136A is located below uppermost surface 120a of nitride semiconductor layer 120 in active region 101. In the present variation, second recessed portion 136A does not penetrate through barrier layer 126. In other words, also in inactive region 102, barrier layer 126 remains and is the uppermost layer of nitride semiconductor layer 120. Contact surface 120b that is the bottom surface of second recessed portion 136A is the surface of barrier layer 126. Lower electrode 150 of capacitor 20 is in contact with barrier layer 126 in inactive region 102, at a position lower than uppermost surface 120a in active region 101 (a position close to substrate 110).

In the present variation, since second recessed portion 136A is provided, the thickness of barrier layer 126 in inactive region 102 is less than the thickness of barrier layer 126 in active region 101. Since piezoelectric polarization is reduced due to barrier layer 126 having a smaller thickness in inactive region 102, 2DEG 125 does not form. Consequently, as with Embodiment 1, the carrier concentration of channel layer 124 in inactive region 102 becomes less than 1×10¹⁵ cm-3 at room temperature. Accordingly, as with Embodiment 1, it is possible to improve the high-frequency characteristics of nitride semiconductor device 1A.

The same also applies to a case in which resistive element 21 or inductor 22 is included instead of capacitor 20. FIG. 3B is a cross-sectional view of nitride semiconductor device 2A according to the present variation that includes resistive element 21 as a passive element. FIG. 3C is a cross-sectional view of nitride semiconductor device 3A according to the present variation that includes inductor 22 as a passive element. As shown in FIG. 3B and FIG. 3C, nitride semiconductor devices 2A and 3A differ from nitride semiconductor devices 2 and 3 in that second recessed portion 136A is provided instead of second recessed portion 136, respectively. Each of metal layers 155 and 156 is in contact with barrier layer 126 in inactive region 102, at a position lower than uppermost surface 120a in active region 101 (a position close to substrate 110). As with Embodiment 1, it is also possible to improve the high-frequency characteristics of nitride semiconductor device 2A including resistive element 21 and nitride semiconductor device 3A including inductor 22.

### Variation 2

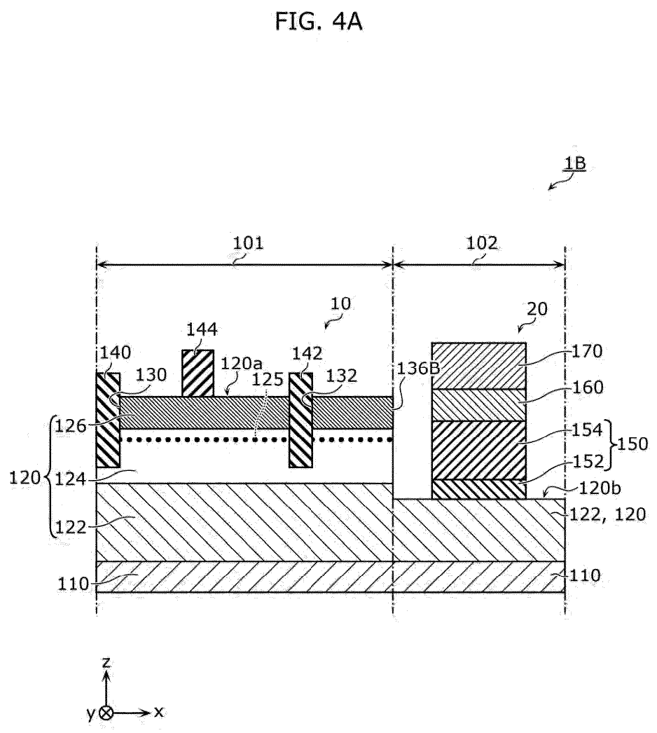

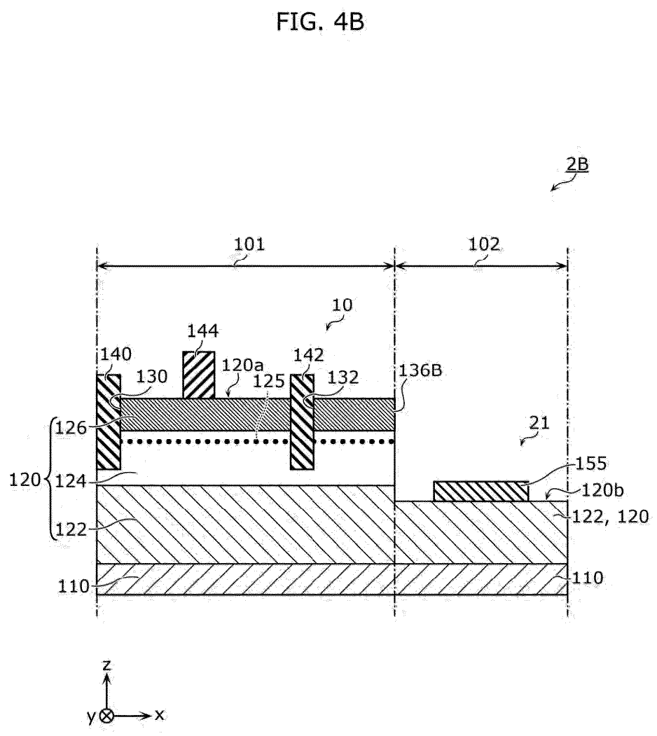

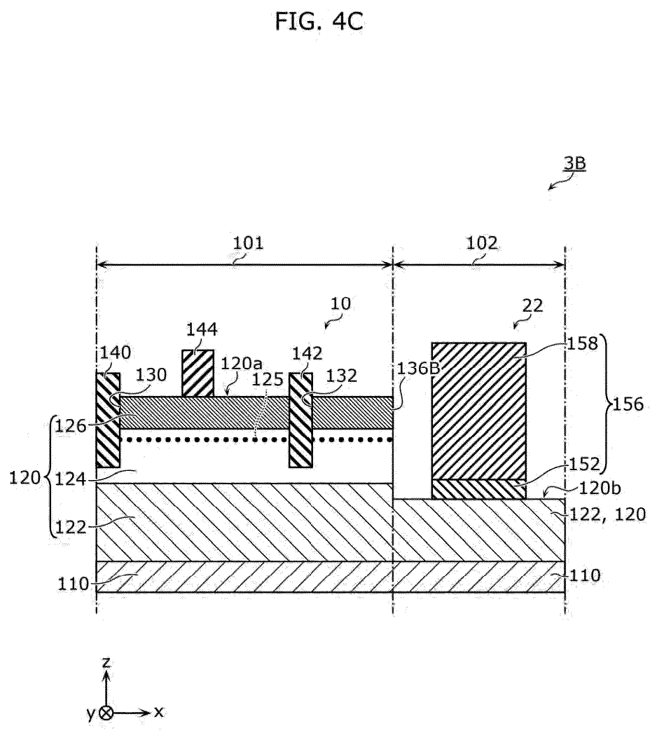

FIG. 4A is a cross-sectional view of nitride semiconductor device 1B according to the present variation that includes capacitor as a passive element. As shown in FIG. 4A, nitride semiconductor device 1B differs from nitride semiconductor device 1 in that second recessed portion 136B is provided instead of second recessed portion 136.

Second recessed portion 136B is provided to inactivate nitride semiconductor layer 120. The bottom surface (contact surface 120b) of second recessed portion 136B is located below uppermost surface 120a of nitride semiconductor layer 120 in active region 101. In the present variation, second recessed portion 136B penetrates through barrier layer 126 and channel layer 124 to buffer layer 122. Contact surface 120b that is the bottom surface of second recessed potion 136B is the surface of buffer layer 122. Neither barrier layer 126 nor channel layer 124 is provided in inactive region 102. In inactive region 102, buffer layer 122 is the uppermost layer of nitride semiconductor layer 120. Lower electrode 150 is in contact with buffer layer 122 in inactive region 102, at a position lower than uppermost surface 120a in active region 101 (a position close to substrate 110).

Buffer layer 122 is an undoped nitride semiconductor layer, and the carrier concentration of buffer layer 122 becomes less than 1×10¹⁵ cm⁻³ at room temperature. Accordingly, as with Embodiment 1, it is possible to improve the high-frequency characteristics of nitride semiconductor device 1B.

The same also applies to a case in which resistive element 21 or inductor 22 is included instead of capacitor 20. FIG. 4B is a cross-sectional view of nitride semiconductor device 2B according to the present variation that includes resistive element 21 as a passive element. FIG. 4C is a cross-sectional view of nitride semiconductor device 3B according to the present variation that includes inductor 22 as a passive element. As shown in FIG. 4B and FIG. 4C, nitride semiconductor devices 2B and 3B differ from nitride semiconductor devices 2 and 3 in that second recessed portion 136B is provided instead of second recessed portion 136, respectively. Each of metal layers 155 and 156 is in contact with buffer layer 122 in inactive region 102, at a position lower than uppermost surface 120a in active region 101 (a position close to substrate 110). As with Embodiment 1, it is also possible to improve the high-frequency characteristics of nitride semiconductor device 2B including resistive element 21 and nitride semiconductor device 3B including inductor 22.

It should be noted that buffer layer 122 may include an impurity region doped with C or Fe. Lower electrode 150 may be in contact with the impurity region. The resistance of the impurity region doped with C or Fe is increased. Since operation variation is thereby reduced, it is possible to improve the high-frequency characteristics of capacitor 20. Doping with C or Fe is performed at the time of crystal growth. For this reason, unlike a case of ion injection, it is possible to maintain a crystal structure.

Additionally, in the present variation, although a portion of buffer layer 122 is also removed in inactive region 102, buffer layer 122 need not be removed. To put it another way, contact surface 120b in inactive region 102 may be as high as the interface between channel layer 124 and buffer layer 122 in active region 101.

### Variation 3

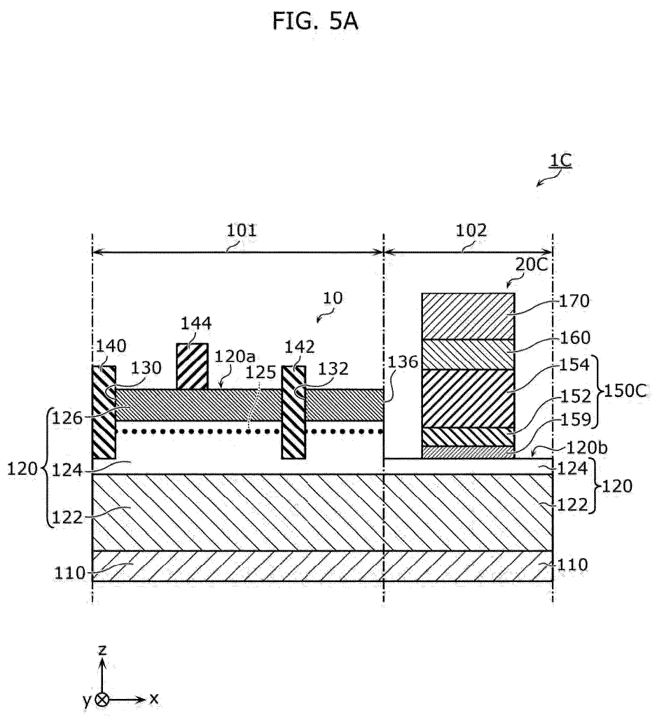

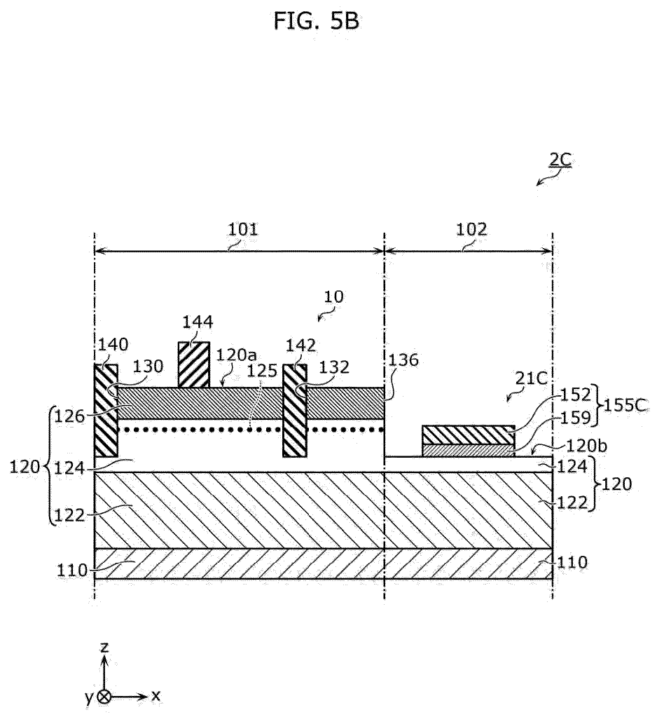

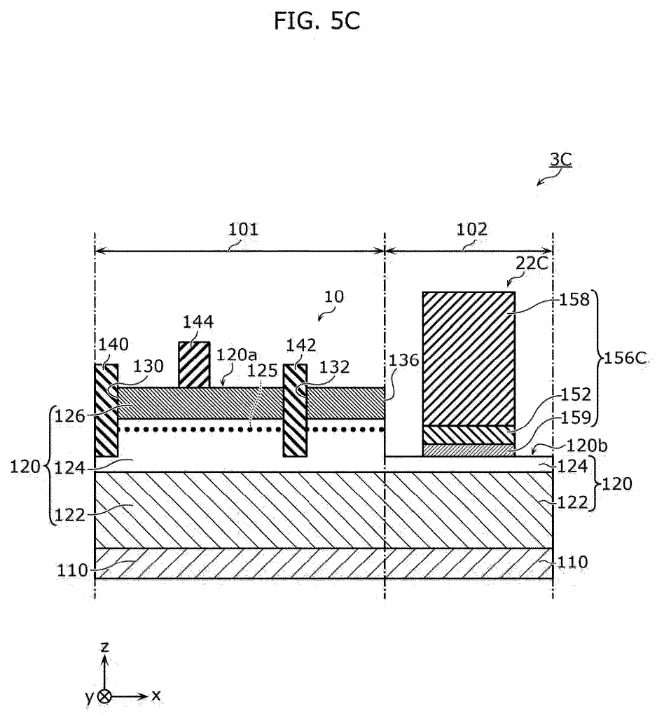

FIG. 5A is a cross-sectional view of nitride semiconductor device 1C according to the present variation that includes capacitor 20C as a passive element. As shown in FIG. 5A, nitride semiconductor device 1C differs from nitride semiconductor device 1 in including capacitor 20C instead of capacitor 20. Capacitor 20C differs from capacitor 20 in including lower electrode 150C instead of lower electrode 150.

Lower electrode 150C includes metal underlayer 159 provided between barrier metal layer 152 and nitride semiconductor layer 120. Metal underlayer 159 includes a hexagonal close-packed (hcp) structure including at least one element selected from a group consisting of Ti, Ta, W, and Hf. Metal underlayer 159 has, for example, a thickness of at least 2 nm and at most 50 nm, and has a thickness of 10 nm as an example. However, the present variation is not limited to this example.

The lattice constant of metal underlayer 159 along the a-axis multiplied by √2 is larger than or equal to the lattice constant of barrier metal layer 152, and is smaller than or equal to the lattice constant of nitride semiconductor layer 120 along the a-axis in contact surface 120b with lower electrode 150C multiplied by √2. For example, the following inequality (4) is satisfied, where the lattice constant of metal underlayer 159 along the a-axis is denoted by “a”.

$$a 1 \times √ 2 \geq a 4 \times √ 2 \geq a 2 \qquad ( 4 )$$

Since metal underlayer 159 is provided, it is possible to enhance the adhesion between barrier metal layer 152 and nitride semiconductor layer 120 (channel layer 124) while maintaining the crystallinity of lower electrode 150C.

The same also applies to a case in which a resistive element or an inductor is included instead of capacitor 20. FIG. 5B is a cross-sectional view of nitride semiconductor device 2C according to the present variation that includes resistive element 21C as a passive element. FIG. 5C is a cross-sectional view of nitride semiconductor device 3C according to the present variation that includes inductor 22C as a passive element.

In nitride semiconductor device 2C shown in FIG. 5B, resistive element 21C includes metal layer 155C. Metal layer 155C includes metal underlayer 159 provided between barrier metal layer 152 and channel layer 124. It should be noted that barrier metal layer 152 is identical to metal layer 155 included in nitride semiconductor device 2 according to Embodiment 1.

In nitride semiconductor device 3C shown in FIG. 5C, inductor 22C includes metal layer 156C. Metal layer 156C includes metal underlayer 159 provided between barrier metal layer 152 and channel layer 124.

As with nitride semiconductor device 1C, nitride semiconductor device 2C including resistive element 21C and nitride semiconductor device 3C including inductor 22C also make it possible to enhance the adhesion of metal layers 155C and 156C while maintaining the crystallinity of metal layers 155C and 156C.

### [Manufacturing Method]

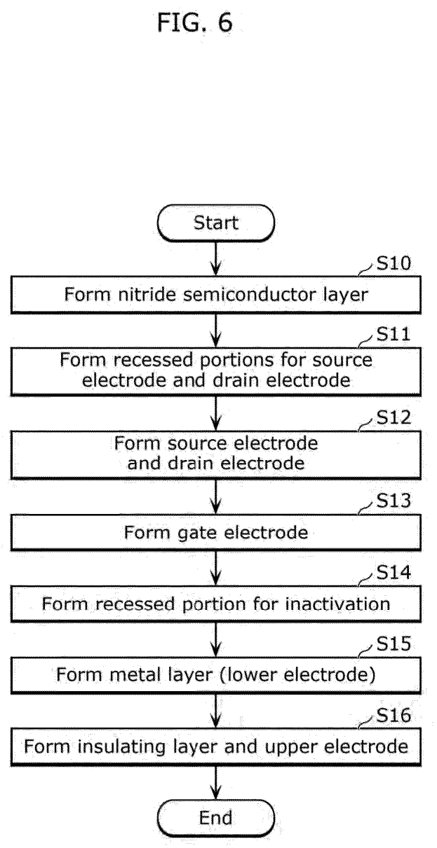

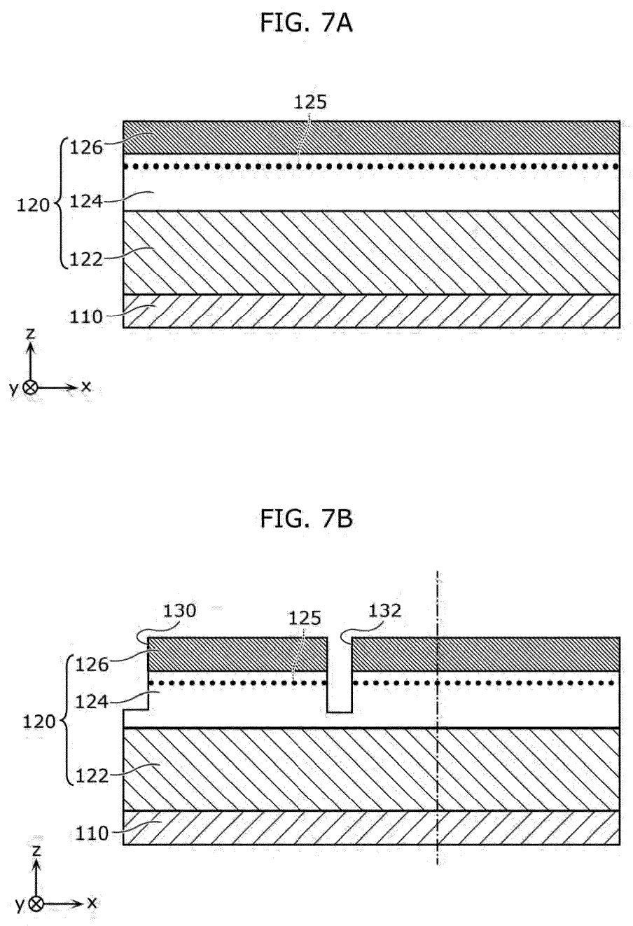

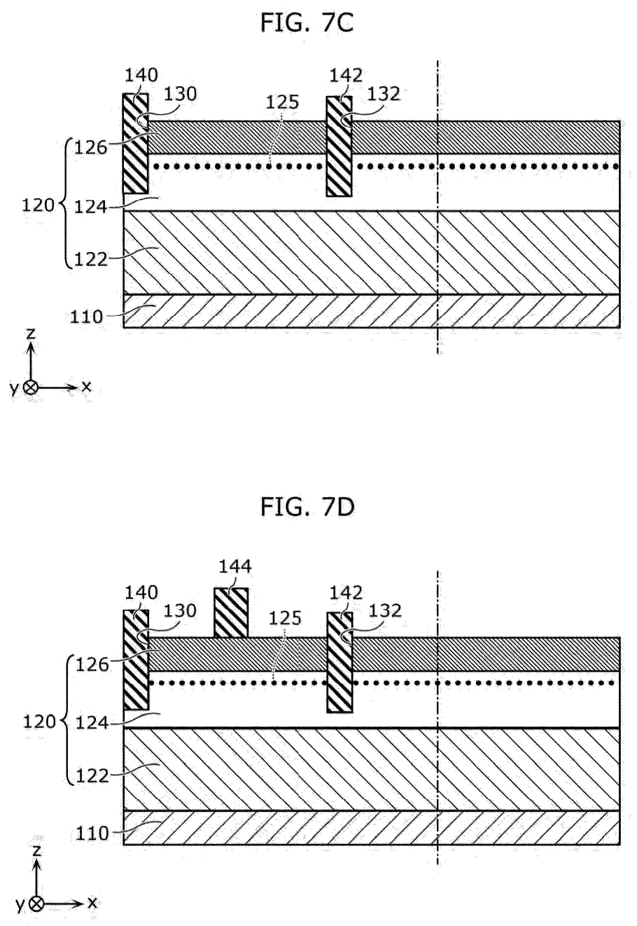

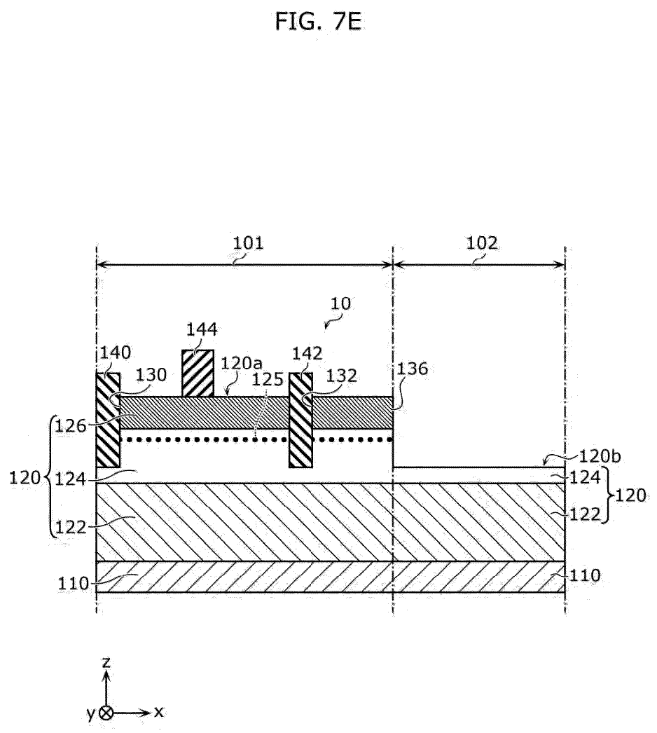

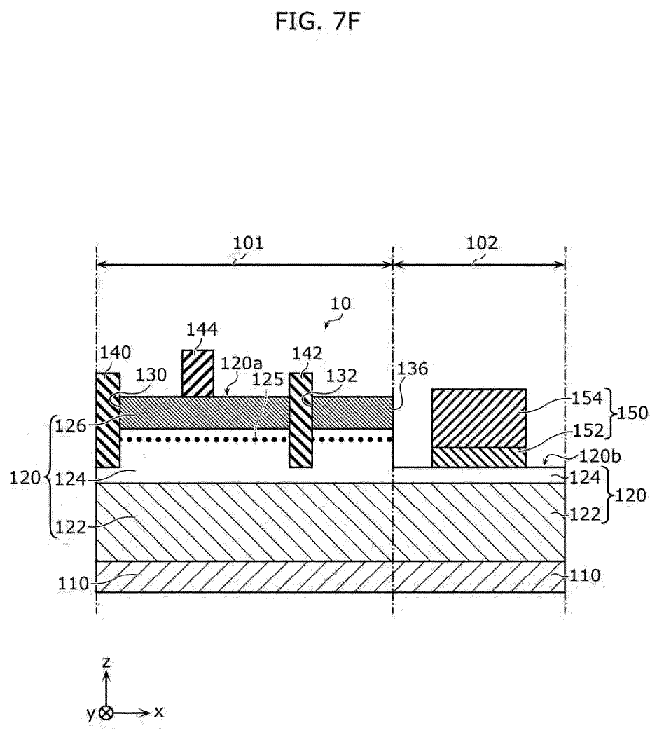

Subsequently, a method for manufacturing nitride semiconductor device 1 according to Embodiment 1 is described. FIG. 6 is a flow chart showing a first example of a method for manufacturing nitride semiconductor device 1 according to the present embodiment. FIG. 7A to FIG. 7F are each a cross-sectional view for illustrating a process included in the first example of the method for manufacturing nitride semiconductor device 1 according to the present embodiment.

As shown in FIG. 6 and FIG. 7A, first, nitride semiconductor layer 120 is formed on substrate 110 (S10). Specifically, buffer layer 122, channel layer 124, and barrier layer 126 are formed in the order stated. The formation of each layer is performed by growing a nitride semiconductor via epitaxial growth such as a metal-organic chemical vapor deposition (MOCVD) method. When buffer layer 122 is formed, impurities for increasing resistance such as C or Fe may be doped.

Next, as shown in FIG. 7B, first recessed portion 130 for source electrode 140 and first recessed portion 132 for drain electrode 142 are formed (S11). For example, a resist pattern in a predetermined shape is formed by photolithography, and first recessed portions 130 and 132 are formed by removing barrier layer 126 and a portion of channel layer 124 within a predetermined range by dry etching using the resist pattern.

Then, as shown in FIG. 7C, source electrode 140 and drain electrode 142 are formed in first recessed portions 130 and 132, respectively (S12). For example, a metal film is formed to cover at least first recessed portions 130 and 132 by electron beam (EB) deposition or sputtering, and source electrode 140 and drain electrode 142 are formed by patterning the formed metal film by etching. After that, as shown in FIG. 7D, gate electrode 144 is formed on nitride semiconductor layer 120 (S13). For example, a metal film is formed to cover at least a region between source electrode 140 and drain electrode 142 by the EB deposition or sputtering, and gate electrode 144 is formed by patterning the formed metal film by etching. It should be noted that the process of forming gate electrode 144 may be performed before the process of forming source electrode 140 and drain electrode 142.

Next, as shown in FIG. 7E, second recessed portion 136 for inactivation is formed (S14). For example, a resist pattern in a predetermined shape is formed by photolithography, and second recessed portion 136 is formed by removing barrier layer 126 and a portion of channel layer 124 within inactive region 102 by dry etching using the resist pattern. In inactive region 102, by removing barrier layer 126, 2DEG 125 in channel layer 124 does not form, and it is possible to cause a carrier concentration at room temperature to be less than 1×10¹⁵ cm⁻³.

Then, as shown in FIG. 7F, a metal layer (specifically lower electrode 150) that is in contact with nitride semiconductor layer 120 in inactive region 102 is formed (S15). Specifically, barrier metal layer 152 and low-resistance metal layer 154 are formed on contact surface 120b in the order stated. For example, a metal film is formed to cover at least contact surface 120b in inactive region 102 by the EB deposition or sputtering, and lower electrode 150 is formed by patterning the formed metal film by etching. At this time, lower electrode 150 is formed to be in the coherent state or the metamorphic state relative to nitride semiconductor layer 120 (channel layer 124). Specifically, the growth rate of an electrode material is reduced. For example, power to be supplied is reduced in a case of sputtering, and temperature is lowered or a distance between a target and a material is increased in a case of the EB deposition. Accordingly, it is possible to reduce the growth rate of the electrode material and form lower electrode 150 that is in the coherent state or the metamorphic state relative to nitride semiconductor layer 120 (channel layer 124). Finally, in inactive region 102, insulating layer 160 is formed on the metal layer (lower electrode 150), and upper electrode 170 is formed on insulating layer 160 formed (S16). For example, after an insulating film is deposited to cover at least lower electrode 150 by a plasma chemical vapor deposition (CVD) method, insulating layer 160 is formed by removing a portion of the deposited insulating film by etching. A metal film is formed to cover at least insulating layer 160 by the EB deposition or sputtering, and upper electrode 170 is formed by patterning the formed metal film by etching.

It is possible to manufacture nitride semiconductor device 1 including capacitor 20 shown in FIG. 1A through the processes described above.

By omitting the process of forming insulating layer 160 and upper electrode 170 (S16), it is possible to manufacture nitride semiconductor device 3 including inductor 22. Additionally, by omitting the process of forming insulating layer 160 and upper electrode 170 (S16) and further omitting the formation of low-resistance metal layer 154 in the process of forming the metal layer (S15), it is possible to manufacture nitride semiconductor device 2 including resistive element 21.

The methods for manufacturing nitride semiconductor devices 1, 2, and 3 described above are mere examples, and a change in the order of the processes, a change in the contents of the processes, etc. may be performed.

For example, in the process of forming second recessed portion 136 (S14), only a portion of barrier layer 126 in inactive region 102 may be removed, and barrier layer 126 having a predetermined thickness may be allowed to remain. Accordingly, it is possible to form nitride semiconductor device 1A, 2A, or 3A according to Variation 1. Alternatively, in the process of forming second recessed portion 136, channel layer 124 in inactive region 102 may be completely removed. In addition, a portion of buffer layer 122 in inactive region 102 may be removed. Accordingly, it is possible to form nitride semiconductor device 1B, 2B, or 3B according to Variation 2.

Moreover, second recessed portion 136 may be formed simultaneously with an alignment mark for alignment. The formation of the alignment mark is usually performed between the process of forming nitride semiconductor layer 120 (S10) and the process of forming first recessed portions 130 and 132 (S11).

Furthermore, in the process of forming the metal layer (lower electrode 150) (S15), metal underlayer 159 may be formed before barrier metal layer 152 is formed. For example, a metal film is formed to cover at least contact surface 120b in inactive region 102 by the EB deposition or sputtering, and metal underlayer 159 is formed by patterning the formed metal film by etching. Accordingly, it is possible to form nitride semiconductor device 1C, 2C, or 3C according to Variation 3.

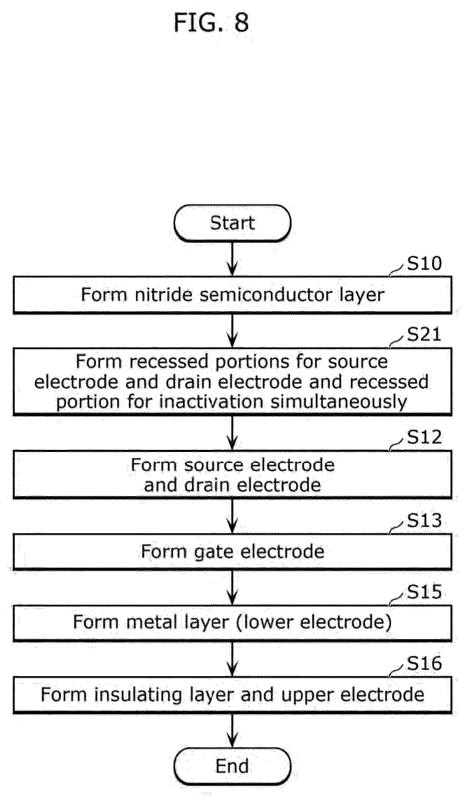

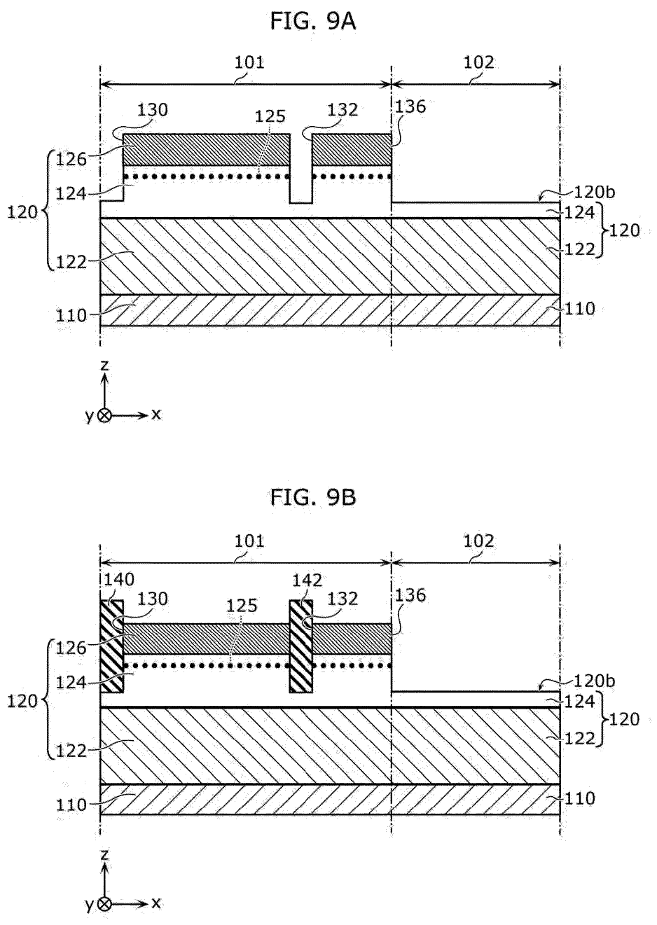

Moreover, the process of forming first recessed portions 130 and 132 (S11) and the process of forming second recessed portion 136 (S14) may be simultaneously performed. FIG. 8 is a flow chart showing a second example of the method for manufacturing nitride semiconductor device 1 according to the present embodiment. FIG. 9A and FIG. 9B are each a cross-sectional view for illustrating a process included in the second example of the method for manufacturing nitride semiconductor device 1 according to the present embodiment.

As shown in FIG. 8 and FIG. 9A, after nitride semiconductor layer 120 is formed, first recessed portion 130 for source electrode 140, first recessed portion 132 for drain electrode 142, and second recessed portion 136 for inactivation are simultaneously formed (S21). For example, a resist pattern in a predetermined shape is formed by photolithography, and first recessed portions 130 and 132 and second recessed portion 136 are simultaneously formed by removing barrier layer 126 within each of a predetermined range in active region 101 and inactive region 102 and a portion of channel layer 124. Since first recessed portions 130 and 132 and second recessed portion 136 are simultaneously formed, the bottom surface of each of first recessed portions 130 and 132 and the bottom surface (contact surface 120b) of second recessed portion 136 are located at the same height.

Then, as shown in FIG. 9B, source electrode 140 and drain electrode 142 are formed in first recessed portions 130 and 132, respectively (S12). As shown in FIG. 8, the subsequent processes are the same as those in the first example shown in FIG. 6, except that the process of forming second recessed portion 136 (S14) is omitted.

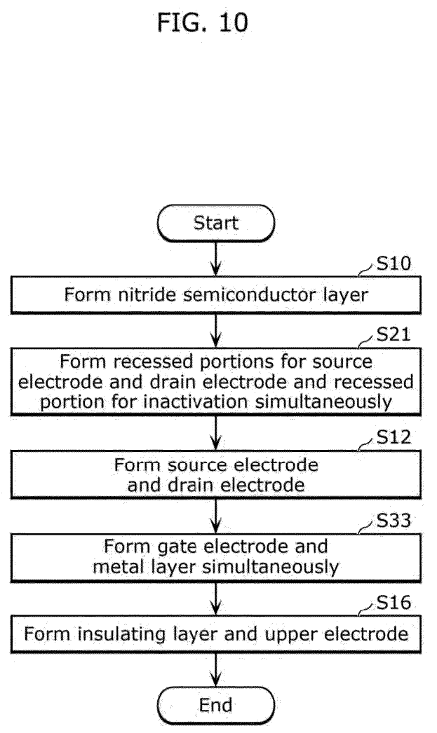

The manufacturing process is simplified by simultaneously forming first recessed portions 130 and 132 and second recessed portion 136. As a result, it is possible to reduce the chance of manufacturing errors etc. and increase yields. Furthermore, the process of forming the metal layer (lower electrode 150) (S15) and the process of forming gate electrode 144 (S13) may be simultaneously performed. FIG. 10 is a flow chart showing a third example of the method for manufacturing nitride semiconductor device 1 according to the present embodiment.

As shown in FIG. 10, the process of forming nitride semiconductor layer 120 (S10) to the process of forming source electrode 140 and drain electrode 142 (S12) are the same as those in the second example of the method for manufacturing nitride semiconductor device 1 shown in FIG. 8. After source electrode 140 and drain electrode 142 are formed, gate electrode 144 and a metal layer (lower electrode 150) are simultaneously formed (S33). Lower electrode 150 is formed at a slow growth rate to be in the coherent state or the metamorphic state relative to nitride semiconductor layer 120 (channel layer 124). The formation rate of gate electrode 144 becomes equal to the growth rate. It is possible to achieve the configuration shown in FIG. 7F by simultaneously forming gate electrode 144 and lower electrode 150. Subsequently, it is possible to manufacture nitride semiconductor device 1 shown in FIG. 1A by forming insulating layer 160 and upper electrode 170 in the order stated.

The manufacturing process is simplified by simultaneously forming gate electrode 144 and the metal layer (lower electrode 150). As a result, it is possible to reduce the chance of manufacturing errors etc. and increase yields.

### Embodiment 2

Subsequently, a nitride semiconductor device according to Embodiment 2 is described. Embodiment 2 differs from Embodiment 1 in that a passivation film that protects the surface of a nitride semiconductor layer is provided. Hereinafter, the differences from Embodiment 1 are mainly described, and the description of common points is omitted or simplified.

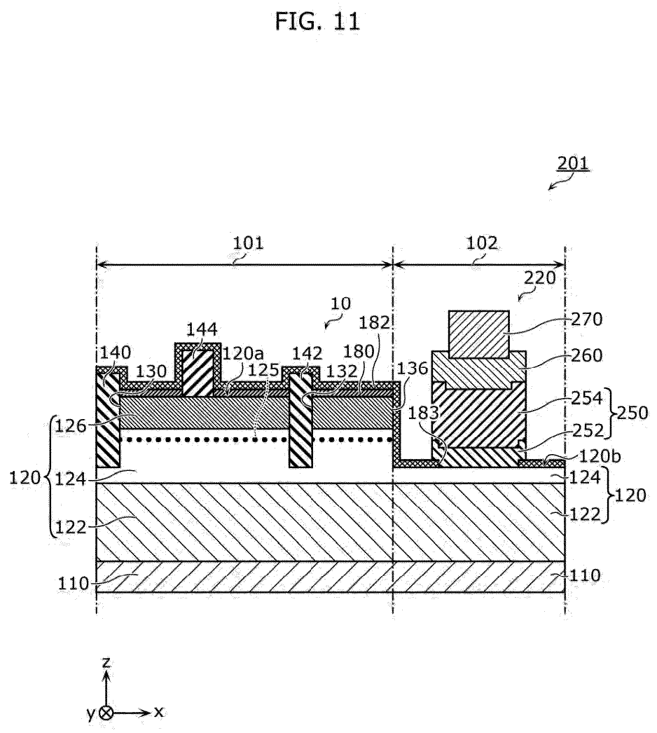

FIG. 11 is cross-sectional view of nitride semiconductor device 201 according to the present embodiment. As shown in FIG. 11, nitride semiconductor device 201 differs from nitride semiconductor device 1 according to Embodiment 1 in including capacitor 220 instead of capacitor 20 and including passivation films 180 and 182.

Passivation film 180 is provided to protect the surface of nitride semiconductor layer 120. Specifically, passivation film 180 covers uppermost surface 120a of nitride semiconductor layer 120 in active region 101. An opening for providing each of source electrode 140, drain electrode 142, and gate electrode 144 in active region 101 is formed in passivation film 180. The openings for source electrode 140 and drain electrode 142 are provided at positions overlapping first recessed portions 130 and 132 in the plan view. In addition, uppermost surface 120a of nitride semiconductor layer 120 is exposed in the opening for gate electrode 144, and it is possible to provide gate electrode 144 in contact with uppermost surface 120a. It should be noted that the opening for gate electrode 144 need not be provided, and gate electrode 144 may be provided on passivation film 180. In this case, it is possible to use passivation film 180 as a gate insulating film.

Passivation film 182 is provided to protect the surface of transistor 10. Specifically, passivation film 182 covers source electrode 140, drain electrode 142, and gate electrode 144 as well as passivation film 180 in active region 101. Additionally, passivation film 182 covers the inner surface of second recessed portion 136 in inactive region 102. Opening 183 for exposing the upper surface (contact surface 120b) of nitride semiconductor layer 120 (channel layer 124) in inactive region 102 is provided in passivation film 182. Passivation films 180 and 182 are each formed using an insulating material. For example, each of passivation films 180 and 182 is a single-layer film or a layered film such as SiN, SiO₂, or SiC, but the present embodiment is not limited to this example. Since passivation films 180 and 182 are provided, it is possible to improve an insulating property between electrodes and an insulating property between an electrode and the metal layer (lower electrode 150), and reduce leak current.

In the present embodiment, capacitor 220 includes lower electrode 250, insulating layer 260, and upper electrode 270. Lower electrode 250 includes barrier metal layer 252 and low-resistance metal layer 254. Barrier metal layer 252, low-resistance metal layer 254, insulating layer 260, and upper electrode 270 correspond to barrier metal layer 152, low-resistance metal layer 154, insulating layer 160, and upper electrode 170 according to Embodiment 1, respectively. The former differs from the latter with respect to their shapes and positions.

Lower electrode 250 is in contact with channel layer 124 exposed in opening 183 provided in passivation film 182. A portion of lower electrode 250 (barrier metal layer 252) is provided on the upper surface of passivation film 182. The length of lower electrode 250 in the x-axis direction is greater than the length of opening 183 in the x-axis direction. A portion of lower electrode 250 overlapping passivation film 182 in the plan view is neither in the coherent state nor the metamorphic state. Lower electrode 250 according to the present embodiment includes the coherent state or the metamorphic state in a range in which lower electrode 250 overlaps opening 183 of passivation film 182 in the plan view.

Upper electrode 270 is smaller than opening 183 in the plan view. In the plan view, entire upper electrode 270 is provided in opening 183. In other words, upper electrode 270 is provided in a position at which upper electrode 270 overlaps, in the plan view, a portion of lower electrode 250 in the coherent state or the metamorphic state. To put it another way, upper electrode 270 is provided in a position opposite to a portion of lower electrode 250 having a high crystallinity and a low resistance, and functions as capacitor 220. Since abnormal growth such as hillocks is inhibited in the position at which the portion of lower electrode 250 overlaps opening 183 in the plan view, it is possible to mitigate a decrease in coverage with insulating layer 260 and electric field crowding. Accordingly, it is possible to mitigate a decrease in breakdown voltage of capacitor 220.

As stated above, by protecting transistor 10 while mitigating the degradation of high-frequency characteristics of capacitor 220, nitride semiconductor device 201 according to the present embodiment makes it possible to improve the reliability. In other words, the present embodiment makes it possible to achieve nitride semiconductor device 201 having superior high-frequency characteristics and a high reliability.

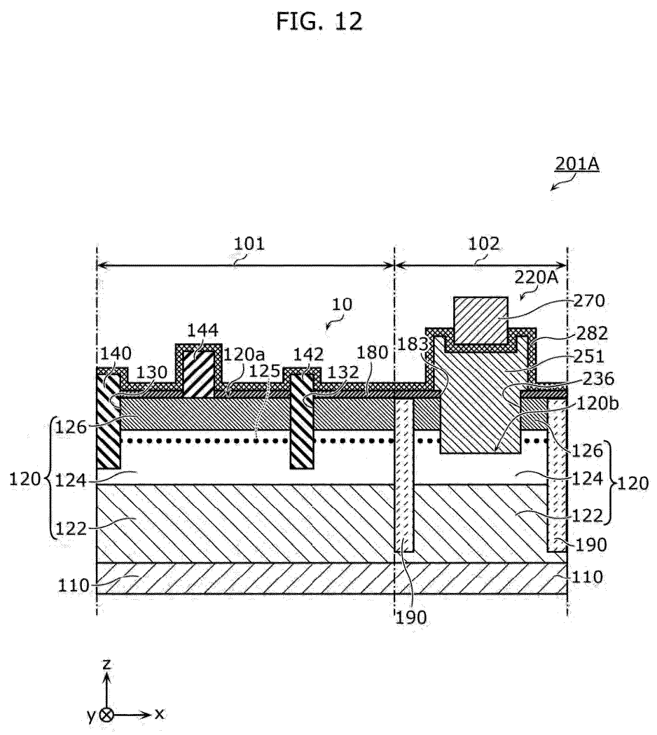

It should be noted that it is also possible to use passivation film 182 as insulating layer 260 of capacitor 220. FIG. 12 is cross-sectional view of nitride semiconductor device 201A according to a variation of the present embodiment.

As shown in FIG. 12, nitride semiconductor device 201A differs from nitride semiconductor device 201 according to Embodiment 2 in including passivation film 282 and capacitor 220A instead of passivation film 182 and capacitor 220 and in that isolation region 190 is provided. Additionally, second recessed portion 236 is provided in inactive region 102 instead of second recessed portion 136.

Capacitor 220A includes lower electrode 251, passivation film 282, and upper electrode 270. A portion of passivation film 282 is provided between lower electrode 251 and upper electrode 270.

Lower electrode 251 corresponds to lower electrode 250 and differs from lower electrode 250 in that lower electrode 251 is provided to embed second recessed portion 236. It should be noted that though not shown in the figure, lower electrode 251 includes a layered structure of a barrier metal layer and a low-resistance metal layer. Lower electrode 251 is in contact with channel layer 124 via contact surface 120b that is the bottom surface of second recessed portion 236. Accordingly, lower electrode 251 includes the coherent state or the metamorphic state in a range in which lower electrode 251 overlaps the bottom surface (contact surface 120b) of second recessed portion 236 in the plan view.

In the example shown in FIG. 12, lower electrode 251 is also in contact with the inner wall surface of second recessed portion 236. Specifically, lower electrode 251 is also in contact with barrier layer 126, and is in contact with 2DEG 125 that forms in the vicinity of an interface between barrier layer 126 and channel layer 124. For this reason, isolation region 190 is provided to block electrical connection between lower electrode 251 and the channel of transistor 10.

Isolation region 190 is a region to which impurities for increasing the resistance of a nitride semiconductor such as C or Fe are added. Isolation region 190 is provided at least in channel layer 124 to block 2DEG 125. For example, isolation region 190 is provided by ion injection to be contiguous from the outermost surface of barrier layer 126 to channel layer 124 and buffer layer 122. In the present variation, isolation region 190 is also included in inactive region 102. Stated differently, with regard to 2DEG 125 in active region 101 in which transistor 10 is provided, an area separated by isolation region 190 is viewed as inactive region 102.

Since isolation region 190 is formed by the ion injection, a crystal structure is collapsed. For this reason, even if lower electrode 251 is formed on isolation region 190, lower electrode 251 is neither in the coherent state nor the metamorphic state relative to nitride semiconductor layer 120. In the present variation, a portion of channel layer 124 is exposed by providing second recessed portion 236, and lower electrode 251 is provided on contact surface 120b that is the exposed surface of channel layer 124. Accordingly, it is possible to improve the crystallinity of lower electrode 251, achieve a decrease in resistance, and inhibit abnormal growth such as hillocks.

Moreover, in the present variation, passivation film 282 functions as an insulating layer of capacitor 220A. It is possible to simplify the manufacturing process, compared to a case in which an insulating layer is formed exclusively for capacitor 220A. Accordingly, it is possible to reduce the chance of manufacturing errors etc. and increase yields.

It should be noted that Embodiment 2 and the variation show the examples in which nitride semiconductor devices 201 and 201A each include the capacitor as the passive element, as with Embodiment 1, nitride semiconductor devices 201 and 201A may each include a resistive element or an inductor. Additionally, it is also possible to apply each of the variations applied to Embodiment 1 to nitride semiconductor devices 201 and 201A.

### Other Embodiments

Although the nitride semiconductor devices according to one or more aspects are described above based on the embodiments, the present disclosure is not limited to these embodiments. Forms obtained by various modifications to the present embodiments that can be conceived by a person skilled in the art as well as forms realized by combining constituent elements in different embodiments are included within the scope of the present disclosure, as long as they do not depart from the essence of the present disclosure.

For example, a plurality of passive elements may be provided in inactive region 102. For example, at least one element selected from a group consisting of capacitor 20, resistive element 21, and inductor 22 may be provided in inactive region 102 in a plural form. The plurality of passive elements may be electrically connected to each other or electrically separated. Likewise, a plurality of active elements may be provided in active region 101.

Moreover, for example, first recessed portions 130 and 132 need not be provided, and source electrode 140 and drain electrode 142 need not each be provided on the upper surface of barrier layer 126. In other words, source electrode 140 and drain electrode 142 need not be in contact with channel layer 124 and 2DEG 125. Furthermore, for example, nitride semiconductor layer 120 need not include channel layer 124 and barrier layer 126. Nitride semiconductor layer 120 may be a nitride semiconductor layer including GaN or InGaN etc. to which n-type impurities such as Si are added. To put it another way, transistor 10 need not be a HEMT and may be another FET such as a metal-oxide-semiconductor-field-effect transistor (MOSFET).

Moreover, for example, the metal layer that is in the coherent state or the metamorphic state relative to nitride semiconductor layer 120 may be formed in the same process as source electrode 140 or drain electrode 142.

Furthermore, in each of the above-described embodiments, various changes, replacement, addition, omission, etc. can be performed within the scope of the claims or equivalent range thereof.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The nitride semiconductor device according to the present disclosure can be used for, for example, power amplifiers for high-power or high-frequency application, wireless communication base stations or terminal equipment in which the power amplifiers are used, or wireless power supply devices that perform power transmission using microwaves.

1. A nitride semiconductor device including an active element and a passive element, the nitride semiconductor device comprising:
a nitride semiconductor layer that is divided into an active region and an inactive region in a plan view; and
a metal layer that is in contact with the nitride semiconductor layer in the inactive region,
wherein the active element is provided in the active region,
the passive element is provided in the inactive region, and
the metal layer includes a coherent state or a metamorphic state relative to the nitride semiconductor layer.

2. The nitride semiconductor device according to claim 1,
wherein the nitride semiconductor layer includes a channel layer and a barrier layer provided above the channel layer, and
the active element contains a two-dimensional electron gas formed in a vicinity of an interface between the channel layer and the barrier layer.

3. The nitride semiconductor device according to claim 2,
wherein the channel layer has a carrier concentration of at least 1×10¹⁵ cm⁻³ in the active region.

4. The nitride semiconductor device according to claim 1,
wherein the nitride semiconductor layer includes a layered structure including a plurality of layers, and
an uppermost layer of the nitride semiconductor layer has a carrier concentration that is less than 1×10¹⁵ cm⁻³ in the inactive region.

5. The nitride semiconductor device according to claim 1,
wherein a contact surface between the nitride semiconductor layer and the metal layer in the inactive region is located lower than an uppermost surface of the nitride semiconductor layer in the active region.

6. The nitride semiconductor device according to claim 2,
wherein the nitride semiconductor layer further includes a buffer layer provided below the channel layer, and
the metal layer is in contact with the buffer layer in the inactive region.

7. The nitride semiconductor device according to claim 1,
wherein the nitride semiconductor layer includes an impurity region doped with C or Fe, and
the metal layer is in contact with the impurity region in the inactive region.

8. The nitride semiconductor device according to claim 1,
wherein the metal layer includes:
a barrier metal layer; and
a low-resistance metal layer located above the barrier metal layer and having a resistance lower than a resistance of the barrier metal layer.

9. The nitride semiconductor device according to claim 1,
wherein the passive element is a resistive element including the metal layer.

10. The nitride semiconductor device according to claim 1,
wherein the passive element is a capacitor including the metal layer as a lower electrode.

11. The nitride semiconductor device according to claim 1,
wherein the passive element is an inductor including the metal layer.

12. The nitride semiconductor device according to claim 8,
wherein the barrier metal layer has a lattice constant that is larger than a lattice constant of the low-resistance metal layer and is less than or equal to √2 times a lattice constant of the nitride semiconductor layer along an a-axis in the contact surface with the metal layer.

13. The nitride semiconductor device according to claim 12,
wherein the low-resistance metal layer and the barrier metal layer each have a lattice constant that is at least 90% of √2 times the lattice constant of the nitride semiconductor layer along the a-axis in the contact surface with the metal layer.

14. The nitride semiconductor device according to claim 8,
wherein the low-resistance metal layer includes a face-centered cubic lattice structure including at least one element selected from a group consisting of Al, Cu, Au, Ag, and Pt.

15. The nitride semiconductor device according to claim 8,
wherein the barrier metal layer includes an NaCl-type structure including: at least one element selected from a group consisting of Ti, Ta, W, and Hf; and an element including at least one of N or C.

16. The nitride semiconductor device according to claim 8,
wherein the metal layer further includes a layer that is provided between the barrier metal layer and the nitride semiconductor layer, the layer including a hexagonal close-packed structure including at least one element selected from a group consisting of Ti, Ta, W, and Hf.

17. The nitride semiconductor device according to claim 1,
wherein the active element includes a gate electrode, a source electrode, and a drain electrode, and
at least one of the gate electrode, the source electrode, or the drain electrode includes a material identical to a material of at least a portion of the metal layer.

18. A method for manufacturing a nitride semiconductor device including an active element and a passive element, the method comprising:
forming a nitride semiconductor layer that is divided into an active region and an inactive region in a plan view; and
forming a metal layer that is in contact with the nitride semiconductor layer in the inactive region,
wherein the active element is provided in the active region,
the passive element is provided in the inactive region, and
the metal layer includes a coherent state or a metamorphic state relative to the nitride semiconductor layer.

19. The method for manufacturing the nitride semiconductor device according to claim 18, the method comprising:
forming a first recessed portion in the nitride semiconductor layer;
forming a source electrode and a drain electrode of the active element in the first recessed portion;
forming a gate electrode of the active element on the nitride semiconductor layer; and
forming a second recessed portion in the nitride semiconductor layer before forming the metal layer,
wherein in the forming of the metal layer, the metal layer is formed in a bottom surface of the second recessed portion.

20. The method for manufacturing the nitride semiconductor device according to claim 19,
wherein the forming of the metal layer and the forming of the gate electrode are performed simultaneously,
the passive element is a capacitor that includes the metal layer as a lower electrode, and
the method further comprises:
forming an insulating layer on the metal layer; and
forming an upper electrode on the insulating layer.
